(19) United States
(12) Patent Application Publication
(10) Pub. No.: US 2025/0228049 A1
(43) Pub. Date: Jul. 10, 2025

(54) DISPLAY APPARATUS AND METHOD OF MANUFACTURING THE SAME

(71) Applicant: Samsung Display Co., Ltd., Yongin-si (KR)

(72) Inventor: Yoshiaki Sakamoto, Yongin-si (KR)

(21) Appl. No.: 19/009,782

(22) Filed: Jan. 3, 2025

(30) Foreign Application Priority Data
Jan. 4, 2024 (KR) 10-2024-0001731

(51) Int. Cl. H10H 29/37; H10H 29/01; H10H 29/49; H10K 59/12; H10K 59/122; H10K 59/131

(52) U.S. Cl. CPC H10H 29/37; H10H 29/012; H10H 29/49; H10K 59/1201; H10K 59/122; H10K 59/131

(57) ABSTRACT

A display apparatus includes a substrate having a display area and a non-display area surrounding the display area, a pixel circuit layer on the substrate, the pixel circuit layer including a pixel circuit and a planarization layer covering the pixel circuit, a first main pixel electrode on the planarization layer, a peripheral pixel electrode on the planarization layer, the peripheral pixel electrode being spaced from the first main pixel electrode and surrounding the first main pixel electrode in a plan view, a bank layer including a first opening exposing a central portion of the first main pixel electrode, a first intermediate layer corresponding to the first main pixel electrode and arranged within the first opening, and an opposite electrode covering the bank layer and the first intermediate layer.

### CROSS-REFERENCE TO RELATED APPLICATION

The present application claims priority to and the benefit of Korean Patent Application No. 10-2024-0001731, filed on Jan. 4, 2024, in the Korean Intellectual Property Office, the entire content of which is incorporated herein by reference.

### BACKGROUND

### 1. Field

Embodiments of the present disclosure described herein are related to a structure of a display apparatus and a method of manufacturing a display apparatus.

### 2. Description of the Related Art

In general, display apparatuses include light-emitting devices and thin-film transistors on a substrate and may operate to cause (and/or control) the light-emitting devices to emit light (to, e.g., display images). Light-emitting devices convert electrical energy into light energy. Examples of the light-emitting devices include organic light-emitting devices including organic material(s) as a light-emitting material, quantum dot light-emitting devices including quantum dot(s) as a light-emitting material, and/or the like.

For example, each pixel of a display apparatus has a light-emitting device that is arranged between a pixel electrode and an opposite electrode and includes an intermediate layer. Display apparatuses generally control light emission of each pixel or the degree of light emission through thin-film transistor(s) electrically connected to pixel electrodes. Some layers included in the intermediate layer of the light-emitting device are provided (e.g., are commonly provided, e.g., are not patterned) in a plurality of light-emitting devices.

The above information disclosed in this Background section is only for enhancement of understanding of the background of the disclosure and therefore it may contain information that does not constitute prior art.

### SUMMARY

Aspects according to one or more embodiments of the present disclosure are directed toward a display apparatus including a light-emitting device with high light emission efficiency and long lifespan. However, this is only an example, and the scope of the disclosure is not limited thereby.

Additional aspects will be set forth in part in the description which follows and, in part, will be apparent from the description, or may be learned by practice of the presented embodiments of the disclosure.

According to one or more embodiments, a display apparatus includes a substrate having a display area and a non-display area around (e.g., surrounding) the display area, a pixel circuit layer on the substrate, the pixel circuit layer including a pixel circuit and a planarization layer covering the pixel circuit, a first main pixel electrode on the planarization layer, a peripheral pixel electrode on the planarization layer, the peripheral pixel electrode being spaced and/or apart (e.g., spaced apart or separated) from the first main pixel electrode and around (e.g., surrounding) the first main pixel electrode in a plan view, a bank layer including a first opening exposing a central portion of the first main pixel electrode, a first intermediate layer corresponding to the first main pixel electrode and arranged within the first opening, and an opposite electrode covering the bank layer and the first intermediate layer.

In one or more embodiments, the first main pixel electrode and the peripheral pixel electrode may be arranged on a same layer.

In one or more embodiments, the bank layer may cover a top surface and an end of the peripheral pixel electrode.

In one or more embodiments, the display apparatus may further include a second main pixel electrode on the planarization layer and arranged adjacent to the first main pixel electrode, and a second intermediate layer arranged within a second opening of the bank layer which exposes a central portion of the second main pixel electrode.

In one or more embodiments, the peripheral pixel electrode may be between the first main pixel electrode and the second main pixel electrode.

In one or more embodiments, each of the first intermediate layer and the second intermediate layer may include an emission layer including quantum dots.

In one or more embodiments, the display apparatus may further include a first connection wire electrically connected to the first main pixel electrode and configured to transmit an electrical signal from an external device, and a second connection wire electrically connected to the peripheral pixel electrode and configured to transmit an electrical signal from the external device.

In one or more embodiments, the first connection wire may be electrically connected to a plurality of main pixel electrodes arranged with each other along (e.g., in a row in) a first direction.

In one or more embodiments, the first connection wire and the second connection wire may be disconnected within the non-display area.

In one or more embodiments, the first connection wire may be on a layer that is different from the first main pixel electrode.

According to one or more embodiments, a method of manufacturing a display apparatus includes forming a pixel circuit layer including a pixel circuit and a planarization layer covering the pixel circuit, forming a main pixel electrode on the planarization layer, forming a peripheral pixel electrode on the planarization layer, the peripheral pixel electrode being spaced and/or apart (e.g., spaced apart or separated) from the main pixel electrode and around (e.g., surrounding) the main pixel electrode in a plan view, forming a bank layer including an opening exposing a central portion of the main pixel electrode, forming an intermediate layer corresponding to the main pixel electrode within the opening, and forming an opposite electrode covering the bank layer and the intermediate layer.

In one or more embodiments, the main pixel electrode and the peripheral pixel electrode may be deposited through a same process.

In one or more embodiments, the bank layer may be formed to cover a top surface and an end of the peripheral pixel electrode.

In one or more embodiments, the forming of the intermediate layer may include forming, on the main pixel electrode, a material layer for forming the intermediate layer, and drying the material layer.

In one or more embodiments, the forming of the intermediate layer may further include baking the dried material layer.

In one or more embodiments, the forming of the material layer may include discharging, through an inkjet process, an intermediate layer forming material into the opening.

In one or more embodiments, the method may further include forming a first connection wire electrically connected to the main pixel electrode and being further extended (e.g., extending) to be connected to an external device, and forming a second connection wire electrically connected to the peripheral pixel electrode and being further extended (e.g., extending) to be connected to the external device.

In one or more embodiments, the drying of the material layer may include applying an alternating current signal from the external device to the main pixel electrode through the first connection wire, and applying an alternating current signal from the external device to the peripheral pixel electrode through the second connection wire.

In one or more embodiments, the drying of the material layer may further include generating an alternating-current electro-osmosis (ACEO) phenomenon within the material layer.

In one or more embodiments, the method may further include disconnecting the first connection wire and the second connection wire within a non-display area of the substrate.

In one or more embodiments, the method may further include bringing a mobile device close to a back surface of the substrate, the mobile device including an auxiliary substrate, a first auxiliary electrode on the auxiliary substrate, and a second auxiliary electrode on the auxiliary substrate, wherein the first auxiliary electrode has a same area as an area of the main pixel electrode, and the second auxiliary electrode has a same area as an area of the peripheral pixel electrode.

In one or more embodiments, the drying of the material layer may include applying alternating current signals from an external device to the first auxiliary electrode and the second auxiliary electrode.

According to one or more embodiments, a display apparatus includes a substrate having a display area and a non-display area around (e.g., surrounding) the display area, a pixel circuit layer on the substrate, the pixel circuit layer including a pixel circuit and a planarization layer covering the pixel circuit, a first sub-pixel electrode on the planarization layer, a second sub-pixel electrode on the planarization layer and spaced and/or apart (e.g., spaced apart or separated) from the first sub-pixel electrode, a bank layer having a first opening exposing a portion of the first sub-pixel electrode and a portion of the second sub-pixel electrode, a first intermediate layer on the first sub-pixel electrode and the second sub-pixel electrode and arranged within the first opening, and an opposite electrode covering the bank layer and the first intermediate layer.

In one or more embodiments, the first sub-pixel electrode and the second sub-pixel electrode may be arranged on a same layer.

In one or more embodiments, the first sub-pixel electrode and the second sub-pixel electrode may have a same area and may respectively have shapes that are symmetrical with each other.

In one or more embodiments, each of the first sub-pixel electrode and the second sub-pixel electrode may be electrically connected to the pixel circuit.

In one or more embodiments, the display apparatus may further include a first connection wire electrically connected to the first sub-pixel electrode and configured to transmit an electrical signal from an external device, and a second connection wire electrically connected to the second sub-pixel electrode and configured to transmit an electrical signal from the external device.

In one or more embodiments, the display apparatus may further include a third sub-pixel electrode on the planarization layer and arranged adjacent to the second sub-pixel electrode, a fourth sub-pixel electrode on the planarization layer and spaced and/or apart (e.g., spaced apart or separated) from the third sub-pixel electrode, and a second intermediate layer arranged within a second opening of the bank layer which exposes a portion of the third sub-pixel electrode and a portion of the fourth sub-pixel electrode.

In one or more embodiments, each of the first connection wire and the second connection wire may be between the second sub-pixel electrode and the third sub-pixel electrode.

In one or more embodiments, only one selected from among the first connection wire and the second connection wire may be between the second sub-pixel electrode and the third sub-pixel electrode.

In one or more embodiments, each of the first connection wire and the second connection wire may be electrically connected to a plurality of sub-pixel electrodes arranged with each other along (e.g., in a row in) a first direction.

In one or more embodiments, the first connection wire and the second connection wire may be disconnected within the non-display area.

According to one or more embodiments, a method of manufacturing a display apparatus includes forming a pixel circuit layer including a pixel circuit and a planarization layer covering the pixel circuit on a substrate, forming a first sub-pixel electrode on the planarization layer, forming a second sub-pixel electrode on the planarization layer, the second sub-pixel electrode being spaced and/or apart (e.g., spaced apart or separated) from the first sub-pixel electrode, forming a bank layer having an opening exposing a portion of the first sub-pixel electrode and a portion of the second sub-pixel electrode, forming an intermediate layer on the first sub-pixel electrode and the second sub-pixel electrode within the first opening, and forming an opposite electrode covering the bank layer and the intermediate layer.

In one or more embodiments, the first sub-pixel electrode and the second sub-pixel electrode may be deposited through a same process.

In one or more embodiments, the first sub-pixel electrode and the second sub-pixel electrode may be formed in a same shape and to have a same area.

In one or more embodiments, the forming of the intermediate layer may include forming, on the first sub-pixel electrode and the second sub-pixel electrode, a material layer for forming the intermediate layer, and drying the material layer.

In one or more embodiments, the forming of the material layer may include discharging, through an inkjet process, an intermediate layer forming material into the opening.

In one or more embodiments, the method may further include forming a first connection wire electrically connected to the first sub-pixel electrode and being further extended (e.g., extending) to be connected to an external device, and forming a second connection wire electrically connected to the second sub-pixel electrode and being further extended (e.g., extending) to be connected to the external device.

In one or more embodiments, the drying of the material layer may include applying an alternating current signal from the external device to the first sub-pixel electrode through the first connection wire, and applying an alternating current signal from the external device to the second sub-pixel electrode through the second connection wire.

In one or more embodiments, the drying of the material layer may further include generating an alternating-current electro-osmosis (ACEO) phenomenon within the material layer.

In one or more embodiments, the method may further include disconnecting the first connection wire and the second connection wire within a non-display area of the substrate.

In one or more embodiments, the method may further include bringing a mobile device close to a back surface of the substrate, the mobile device including an auxiliary substrate, a first auxiliary electrode on the auxiliary substrate, and a second auxiliary electrode on the auxiliary substrate, wherein the first auxiliary electrode may have a same area as an area of the first sub-pixel electrode, and the second auxiliary electrode may have a same area as an area of the second sub-pixel electrode.

In one or more embodiments, the drying of the material layer may include applying alternating current signals from an external device to the first auxiliary electrode and the second auxiliary electrode.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic perspective view of a display apparatus according to one or more embodiments;

FIG. 2 is an equivalent circuit diagram of a pixel circuit electrically connected to a light-emitting device included in a pixel in the display apparatus of FIG. 1;

FIGS. 3A and 3B are schematic cross-sectional views of display apparatuses according to one or more embodiments;

FIG. 4 is a schematic plan view of a display apparatus according to one or more embodiments;

FIG. 5 is a schematic cross-sectional view of the display apparatus of FIG. 4 taken along the line I-I′ of FIG. 4;

FIGS. 6A-6E are cross-sectional views schematically illustrating a method of manufacturing a display apparatus, according to one or more embodiments;

FIG. 7 is a cross-sectional view schematically illustrating a method of manufacturing a display apparatus, according to one or more embodiments;

FIG. 8 is a schematic plan view of a display apparatus according to one or more embodiments;

FIG. 9 is a schematic cross-sectional view of the display apparatus of FIG. 8 taken along the line II-II′ of FIG. 8;

FIGS. 10A-10E are cross-sectional views schematically illustrating a method of manufacturing a display apparatus, according to one or more embodiments;

FIG. 11 is a cross-sectional view schematically illustrating a method of manufacturing a display apparatus, according to one or more embodiments; and

FIG. 12 is a schematic plan view of a display apparatus according to one or more embodiments.

### DETAILED DESCRIPTION

Reference will now be made in more detail to one or more embodiments, examples of which are illustrated in the accompanying drawings, wherein like reference numerals refer to like elements throughout, and duplicative descriptions thereof may not be provided. In this regard, the present embodiments may have different forms and should not be construed as being limited to the descriptions set forth herein. Accordingly, one or more embodiments are merely described in more detail herein, by referring to the drawings, to explain aspects of the present description.

In the present specification, “including A or B”, “A and/or B”, etc., represents A or B, or A and B.

As used herein, the term “and/or” includes any and all combinations of one or more of the associated listed items. As used herein, expressions such as “at least one of”, “one of”, and “selected from”, when preceding a list of elements, modify the entire list of elements and do not modify the individual elements of the list. For example, “at least one of a, b or c”, “at least one selected from a, b and c”, etc., may indicate only a, only b, only c, both (e.g., simultaneously) a and b, both (e.g., simultaneously) a and c, both (e.g., simultaneously) b and c, all of a, b, and c, or variations thereof.

As used herein, the term “substantially,” “about,” and similar terms are used as terms of approximation and not as terms of degree, and are intended to account for the inherent deviations in measured or calculated values that would be recognized by those of ordinary skill in the art. “Substantially” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “substantially” may mean within one or more standard deviations, or within +30%, 20%, 10%, 5% of the stated value.

Also, any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

Further, the use of “may” when describing embodiments of the present disclosure refers to “one or more embodiments of the present disclosure.” As used herein, the singular forms “a,” “an” and “the” are intended to include the plural forms as well, unless the context clearly indicates otherwise.

Descriptions of features or aspects within each embodiment should typically be considered as available for other similar features or aspects in other embodiments.

In the context of the present application and unless otherwise defined, the terms “use,” “using,” and “used” may be considered synonymous with the terms “utilize,” “utilizing,” and “utilized,” respectively. Further, the use of “may” when describing embodiments of the present invention refers to “one or more embodiments of the present invention.”

Spatially relative terms, such as “on,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the drawings. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

As the present description allows for one or more suitable changes and numerous embodiments, certain embodiments will be illustrated in the drawings and described in more detail in the written description. Effects and features of the disclosure, and methods of achieving them will be clarified with reference to one or more embodiments described herein in more detail with reference to the drawings. However, the disclosure is not limited to the following embodiments and may be embodied in one or more suitable forms.

Hereinafter, embodiments will be described in more detail with reference to the accompanying drawings. When describing embodiments with reference to the accompanying drawings, the same or corresponding elements are denoted by the same reference numerals.

It will be understood that although the terms “first,” “second,” and/or the like may be used herein to describe one or more suitable elements, these elements should not be limited by these terms. These terms are only used to distinguish one element from another.

The singular forms as used herein are intended to include the plural forms as well unless the context clearly indicates otherwise.

It will be further understood that the terms “comprises,” “comprising,” “includes,” “including,” “have,” “having,” “contain,” and “containing,” when used in this specification, specify the presence of the stated features, integers, steps, operations, elements, and/or components, but do not preclude the presence or addition of one or more other features, integers, steps, operations, elements, components, and/or groups thereof.

In this specification, it will be understood that when an element, such as an area, layer, film, region or portion, is referred to as being “on,” “connected to,” or “coupled to” another element, it may be directly on, connected to, or coupled to another element, or one or more intervening elements may be present. In addition, it will also be understood that when an element is referred to as being “between” two elements, it can be the only element between the two elements, or one or more intervening elements may also be present.

Also, sizes of elements in the drawings may be exaggerated or reduced for convenience of explanation. For example, because sizes and thicknesses of elements in the drawings are arbitrarily illustrated for convenience of explanation, the present disclosure is not limited thereto.

When a certain embodiment may be implemented differently, a specific process order may be performed differently from the stated order. For example, two consecutively described processes may be performed substantially at the same time or performed in an order opposite to the stated order.

It will be further understood that, if (e.g., when) layers, regions, or components are referred to as being connected to each other, they may be directly connected to each other or indirectly connected to each other with intervening layers, regions, or components therebetween. For example, if (e.g., when) layers, regions, or elements are referred to as being electrically connected to each other, they may be directly electrically connected to each other or indirectly electrically connected to each other with intervening layers, regions, or elements therebetween.

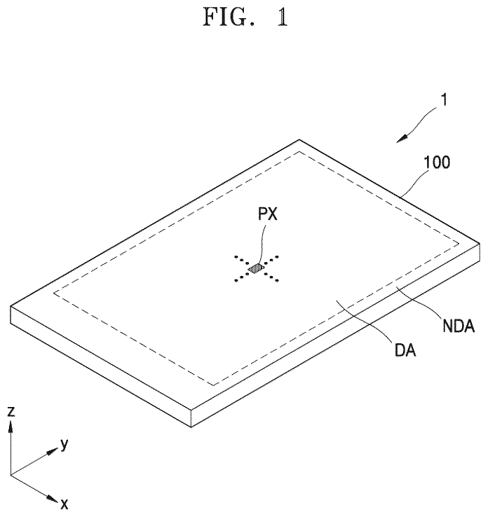

FIG. 1 is a schematic perspective view of a display apparatus 1 according to one or more embodiments.

Referring to FIG. 1, the display apparatus 1 may include a display area DA and a non-display area NDA on a substrate 100.

The display area DA may implement an image. In a plan view, a plurality of pixels PX may be two-dimensionally arranged in the display area DA. In the present specification, the pixels PX refer to sub-pixels that are configured to emit light of different colors. The pixels PX may each be, for example, a red sub-pixel, a green sub-pixel, and/or a blue sub-pixel. The display apparatus 1 may provide an image by using the light emitted from the pixels PX.

The non-display area NDA is an area that does not provide an image. No pixels PX are arranged in the non-display area NDA. The non-display area NDA may completely be around (e.g., surround) the display area DA. A driver or a voltage line configured to provide electrical signals or power to the pixels PX may be arranged in the non-display area NDA. A pad portion, which is an area to which an electronic device or a printed circuit board may be electrically connected, may be arranged in the non-display area NDA.

The display area DA may have a polygonal shape. For example, the display area DA may have a rectangular shape in which a horizontal length thereof is greater than a vertical length thereof, as illustrated in FIG. 1. In one or more embodiments, the display area DA may have a square shape. In one or more embodiments, the display area DA may have other shapes, such as an elliptical shape or a circular shape.

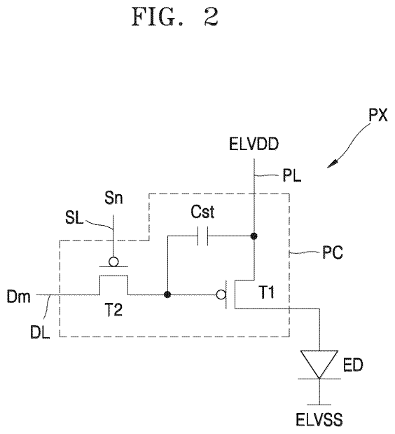

FIG. 2 is an equivalent circuit diagram of a pixel PX in a display apparatus, according to one or more embodiments.

Referring to FIG. 2, the pixel PX may include a pixel circuit PC and a display element (e.g., a light-emitting diode ED) connected to the pixel circuit PC. The pixel circuit PC may include a first thin-film transistor T1, a second thin-film transistor T2, and a storage capacitor Cst. The pixel PX may be configured to emit red light, green light, or blue light through the light-emitting diode ED, or may be configured to emit red light, green light, blue light, or white light through the light-emitting diode ED.

The second thin-film transistor T2, which acts as a switching thin-film transistor, may be connected to a scan line SL and a data line DL and may be configured to transmit, to the first thin-film transistor T1, a data voltage or a data signal Dm input from the data line DL in response to a switching voltage or a switching signal Sn input from the scan line SL. The storage capacitor Cst may be connected to the second thin-film transistor T2 and a driving voltage line PL and may be configured to store a voltage corresponding to a difference between a voltage received from the second thin-film transistor T2 and a first power supply voltage ELVDD supplied to the driving voltage line PL.

The first thin-film transistor T1, which acts as a driving thin-film transistor, may be connected to the driving voltage line PL and the storage capacitor Cst and may be configured to control a driving current flowing from the driving voltage line PL to the light-emitting diode ED according to a voltage value stored in the storage capacitor Cst. The light-emitting diode ED may be configured to emit light having a certain luminance according to the driving current. An opposite electrode (e.g., a cathode) of the light-emitting diode ED may be configured to receive a second power supply voltage ELVSS.

FIG. 2 illustrates that the pixel circuit PC includes two thin-film transistors and one storage capacitor, but in one or more embodiments, the number of thin-film transistors or the number of storage capacitors may be variously changed according to the design of the pixel circuit PC.

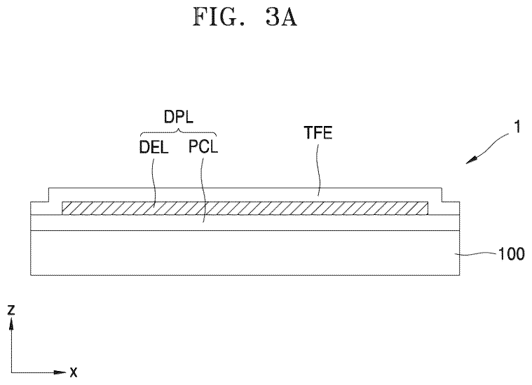

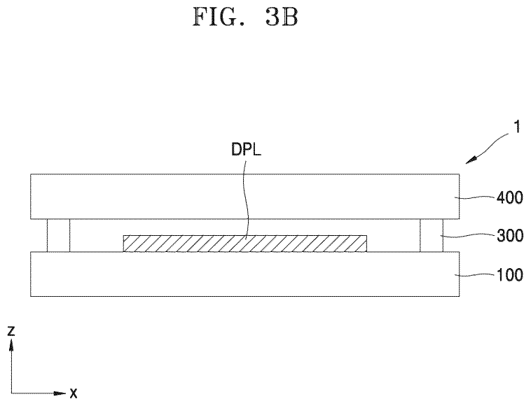

FIG. 3A is a schematic cross-sectional view of a display apparatus 1 according to one or more embodiments. FIG. 3B is a schematic cross-sectional view of a display apparatus 1 according to one or more embodiments.

Referring to FIG. 3A, the display apparatus 1 may include a display layer DPL and a thin-film encapsulation layer TFE on a substrate 100. The display layer DPL may include a pixel circuit layer PCL including a pixel circuit and insulating layers, and a display element layer DEL on the pixel circuit layer PCL and including a plurality of display elements.

The substrate 100 may include glass, metal, or polymer resin. Examples of the polymer resin may include polyethersulfone, polyacrylate, polyetherimide, polyethylene naphthalate, polyethylene terephthalate, polyphenylene sulfide, polyarylate, polyimide, polycarbonate, cellulose acetate propionate, or any mixture thereof. In one or more embodiments, other modifications are possible. For example, the substrate 100 may have a multilayer structure that includes two layers and a barrier layer therebetween, wherein the two layers may include polymer resin and the barrier layer may include an inorganic material (e.g., silicon oxide (SiOₓ), silicon nitride (SiNₓ), silicon oxynitride (SiON), and/or the like).

The display element layer DEL may include display elements, for example, a light-emitting diode. The pixel circuit layer PCL may include the insulating layers and the pixel circuit connected to the light-emitting diode. For example, the pixel circuit layer PCL may include a plurality of transistors, a plurality of storage capacitors, and insulating layers therebetween.

The display elements may be covered with an encapsulation member, such as the thin-film encapsulation layer TFE. The thin-film encapsulation layer TFE may include at least one inorganic encapsulation layer and at least one organic encapsulation layer, which covers the display element layer DEL. The inorganic encapsulation layer may include an inorganic insulating material, such as aluminum oxide (Al₂O₃), titanium oxide (TiO₂), tantalum oxide (Ta₂O₅), hafnium oxide (HfO₂), zinc oxide (ZnO), silicon oxide (SiOₓ), silicon nitride (SiNₓ), or silicon oxynitride (SiON). The organic encapsulation layer may include a polymer-based material. The polymer-based material may include acrylic resin, epoxy-based resin, polyimide, polyethylene, and/or the like. In one or more embodiments, the organic encapsulation layer may include acrylate.

Referring to FIG. 3B, the display apparatus 1 may include a display layer DPL and a sealing substrate 400 on a substrate 100. A sealing member 300 may be between the substrate 100 and the sealing substrate 400. The sealing substrate 400 may be a transparent member. The substrate 100 and the sealing substrate 400 may be bonded to each other by the sealing member 300, so that an internal space between the substrate 100 and the sealing substrate 400 is sealed. In this case, a moisture absorbent or a filler may be located in the internal space. The sealing member 300 may be a sealant. In one or more embodiments, the sealing member 300 may include a material that is curable by a laser. For example, the sealing member 300 may be a frit. For example, the sealing member 300 may include an organic sealant, such as urethane-based resin, epoxy-based resin, and/or acrylic resin, and/or an inorganic sealant, such as silicone. Examples of the urethane-based resin may include urethane acrylate. Examples of the acrylic resin may include butyl acrylate and ethylhexyl acrylate. In one or more embodiments, the sealing member 300 may include a material that is curable by heat.

In one or more embodiments, the display element layer DEL may be covered with the sealing substrate 400 and the sealing member 300 of FIG. 3B along with the thin-film encapsulation layer TFE of FIG. 3A.

A touch electrode layer may be on the thin-film encapsulation layer TFE and/or the sealing substrate 400, and an optical function layer may be on the touch electrode layer. The touch electrode layer may be configured to obtain coordinate information according to an external input, for example, a touch event. The optical function layer may reduce the reflectance of light (e.g., external light) incident from the outside toward the display apparatus 1. In one or more embodiments, the optical function layer may improve color purity of light emitted from the display apparatus 1. In one or more embodiments, the optical function layer may include a retarder and/or a polarizer. The retarder may be a film-type or kind retarder or a liquid crystal coating-type or kind retarder and may include a λ/2 retarder and/or a λ/4 retarder. The polarizer may be a film-type or kind polarizer or a liquid crystal coating-type or kind polarizer. The film-type or kind retarder or polarizer may include a stretched synthetic resin film, and the liquid crystal coating-type or kind retarder or polarizer may include liquid crystals arranged in a certain array. Each of the retarder and the polarizer may further include a protection film.

In one or more embodiments, the optical function layer may include a black matrix and color filters. The color filters may be arranged based on the color of light emitted from each pixel of the display apparatus 1. Each of the color filters may include a red, green, and/or blue pigment and/or dye. In one or more embodiments, each of the color filters may further include, in addition to the pigment and/or dye, quantum dot(s). In one or more embodiments, some color filters may not include (e.g., may exclude any of) the pigment or dye described above and may include scattering particle(s), such as titanium oxide.

An adhesive member may be between the touch electrode layer and the optical function layer. As the adhesive member, any suitable (e.g., general) adhesive members suitable in the art may be employed without limitation. In one or more embodiments, the adhesive member may be a pressure sensitive adhesive (PSA).

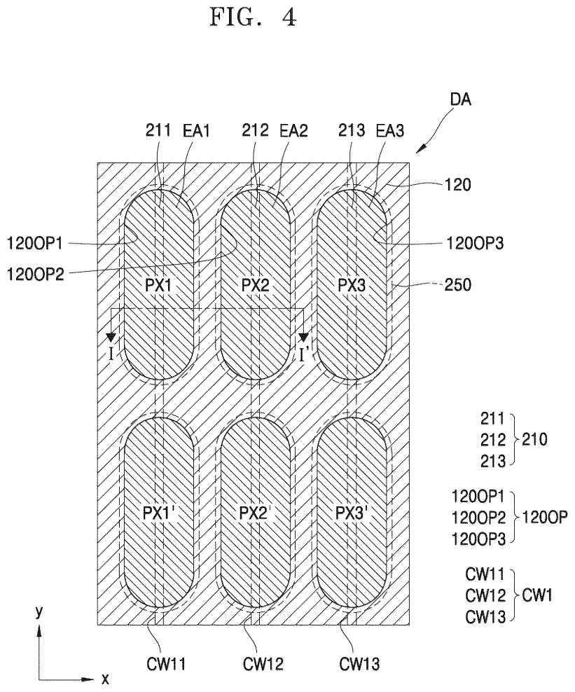

FIG. 4 is a schematic plan view of a display apparatus according to one or more embodiments. FIG. 4 is a schematic enlarged view of a portion of the display area DA in the display apparatus 1 illustrated in FIG. 1. FIG. 4 illustrates a bank layer 120 and a plurality of main pixel electrodes 210 arranged two-dimensionally in a plan view and, the bank layer 120 has openings 120OP exposing the central portions of the main pixel electrodes 210.

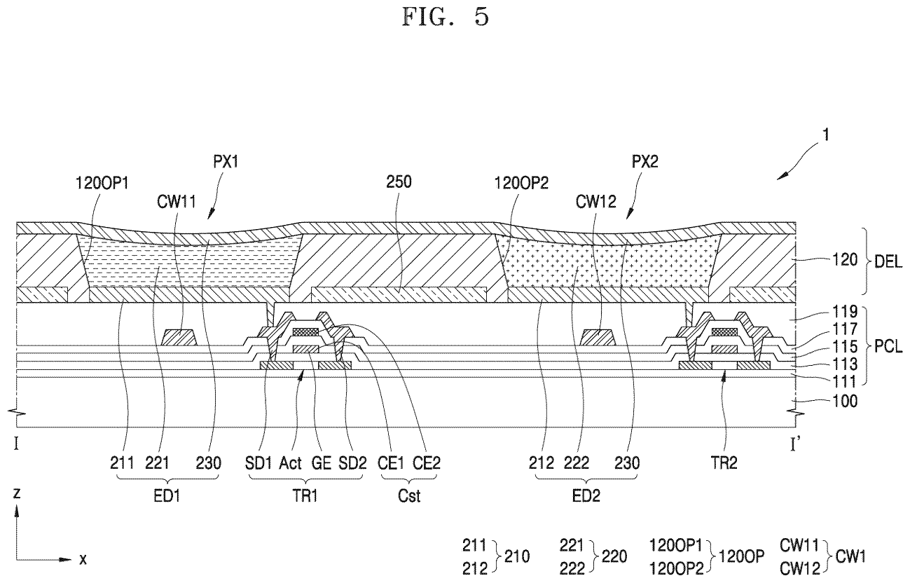

Referring to FIG. 4, the display apparatus may include a plurality of pixels (see, e.g., PX of FIG. 1). The pixels (see PX of FIG. 1) may include a first pixel PX1, a second pixel PX2, and a third pixel PX3. The first pixel PX1 may include a first light-emitting diode (see, e.g., ED1 of FIG. 5), the second pixel PX2 may include a second light-emitting diode (see, e.g., ED2 of FIG. 5), and the third pixel PX3 may include a third light-emitting diode. The first pixel PX1, the second pixel PX2, and the third pixel PX3 may be configured to emit light of different colors. For example, the first pixel PX1 may be configured to emit green light, the second pixel PX2 may be configured to emit red light, and the third pixel PX3 may be configured to emit blue light. The red light may be light in a wavelength band of about 580 nm to about 780 nm, the blue light may be light in a wavelength band of about 380 nm to about 495 nm, and the green light may be light in a wavelength band of about 495 nm to about 580 nm.

Each of the light-emitting diodes may include a pixel electrode, an opposite electrode, and an intermediate layer therebetween. Here, in the present disclosure, the pixel electrode may be referred to as a main pixel electrode 210. For example, as illustrated in FIG. 4, the first pixel PX1 may include a first main pixel electrode 211 of the first light-emitting diode (see, e.g., ED1 of FIG. 5), the second pixel PX2 may include a second main pixel electrode 212 of the second light-emitting diode (see, e.g., ED2 of FIG. 5), and the third pixel PX3 may include a third main pixel electrode 213 of the third light-emitting diode (see, e.g., ED3 of FIG. 5). The first main pixel electrode 211, the second main pixel electrode 212, and the third main pixel electrode 213 may be spaced and/or apart (e.g., spaced apart or separated) from each other on the substrate (see, e.g., 100 of FIG. 5). In the present specification, the expression “in a plan view” refers to a plane viewed from a direction normal (e.g., perpendicular) to the substrate 100. For example, the expression “A and B spaced and/or apart (e.g., spaced apart or separated) from each other in a plan view” refers to “A and B spaced and/or apart (e.g., spaced apart or separated) from each other if (e.g., when) viewed from a direction normal (e.g., perpendicular) to the substrate 100.”

The bank layer 120 may be on the first main pixel electrode 211, the second main pixel electrode 212, and the third main pixel electrode 213 and may cover the edges of each of the first main pixel electrode 211, the second main pixel electrode 212, and the third main pixel electrode 213. For example, the bank layer 120 may have a first opening 1200P1 exposing the central portion of the first main pixel electrode 211, a second opening 120OP2 exposing the central portion of the second main pixel electrode 212, and a third opening 1200P3 exposing the central portion of the third main pixel electrode 213.

In one or more embodiments, emission layers configured to emit light may be respectively located within the first opening 120OP1, the second opening 120OP2, and the third opening 120OP3 of the bank layer 120. The opposite electrode may be on the emission layers. As described above, the stack structure of the main pixel electrode 210, the emission layer, and the opposite electrode may constitute one light-emitting diode. One opening of the bank layer 120 may correspond to one light-emitting diode and may define one emission area.

For example, an emission layer configured to emit red light may be arranged in the first opening 120OP1, and thus, the first opening 120OP1 may define a first emission area EA1. Similarly, an emission layer configured to emit green light may be arranged in the second opening 120OP2, and thus, the second opening 120OP2 may define a second emission area EA2. An emission layer configured to emit blue light may be arranged in the third opening 120OP3, and thus, the third opening 120OP3 may define a third emission area EA3. Accordingly, the area of the first opening 120OP1 may be equal to the area of the first emission area EA1. Of course, the area of the second opening 120OP2 may be equal to the area of the second emission area EA2, and the area of the third opening 120OP3 may be equal to the area of the third emission area EA3.

Each of the first opening 120OP1, the second opening 120OP2, and the third opening 120OP3 may have a circular shape or an elliptical shape if (e.g., when) viewed from a direction (a z-axis direction) normal (e.g., perpendicular) to the substrate (e.g., when viewed in a plan view of the display apparatus 1) (see, e.g., 100 of FIG. 5). For example, each of the first emission area EA1, the second emission area EA2, and the third emission area EA3 may have a circular shape or an elliptical shape if (e.g., when) viewed from a direction (the z-axis direction) normal (e.g., perpendicular) to the substrate (e.g., when viewed in a plan view of the display apparatus 1) (see, e.g., 100 of FIG. 5). FIG. 4 illustrates that each of the first emission area EA1, the second emission area EA2, and the third emission area EA3 has an elliptical shape if (e.g., when) viewed from a direction (the z-axis direction) normal (e.g., perpendicular) to the substrate (e.g., when viewed in a plan view of the display apparatus 1) (see 100 of FIG. 5). However, the present disclosure is not limited thereto. For example, each of the first emission area EA1, the second emission area EA2, and the third emission area EA3 may have a polygonal shape if (e.g., when) viewed from a direction (the z-axis direction) normal (e.g., perpendicular) to the substrate (e.g., when viewed in a plan view of the display apparatus 1) (see 100 of FIG. 5).

In one or more embodiments, the display apparatus according to one or more embodiments may further include, in addition to the main pixel electrodes 210, peripheral pixel electrodes 250. The peripheral pixel electrode 250 may be arranged on the same layer as the main pixel electrode 210 and may include the same material as a material of the main pixel electrode 210. At this time, the peripheral pixel electrode 250 may be spaced and/or apart (e.g., spaced apart or separated) from the main pixel electrode 210.

In one or more embodiments, the peripheral pixel electrode 250 may be around (e.g., surround) the main pixel electrode 210 if (e.g., when) viewed in a direction (e.g., the z-axis direction) normal (e.g., perpendicular) to the substrate (e.g., when viewed in a plan view of the display apparatus 1) (see, e.g., 100 of FIG. 5). Because the bank layer 120 covers the end of the main pixel electrode 210, the peripheral pixel electrode 250 may be to overlap the bank layer 120. However, because the peripheral pixel electrode 250 is arranged on the same layer as the main pixel electrode 210, the bank layer 120 may be on the peripheral pixel electrode 250. For example, the bank layer 120 may cover the top surface of the peripheral pixel electrode 250 and both (e.g., simultaneously) ends of the peripheral pixel electrode 250, and the main pixel electrode 210 and the peripheral pixel electrode 250 may be insulated from each other by the bank layer 120.

In addition, the peripheral pixel electrodes 250 may be between the pixels (see, e.g., PX of FIG. 1) arranged adjacent to each other. For example, the peripheral pixel electrodes 250 may be between the main pixel electrodes 210 arranged adjacent to each other. For example, the peripheral pixel electrodes 250 may be between the first main pixel electrode 211 and the second main pixel electrode 212 and may be between the second main pixel electrode 212 and the third main pixel electrode 213.

In one or more embodiments, the peripheral pixel electrodes 250 may be formed as a single body so as to be shared by the pixels (see, e.g., PX of FIG. 1) adjacent to each other. For example, the peripheral pixel electrodes 250 may be integrally formed between the main pixel electrodes 210. Accordingly, as illustrated in FIG. 4, the peripheral pixel electrode 250 may have a shape that overlaps the bank layer 120 in a plan view of the display apparatus 1. However, the present disclosure is not limited thereto. In one or more embodiments, the peripheral pixel electrodes 250 may be separately formed for each pixel (see, e.g., PX of FIG. 1) while around (e.g., surrounding) the main pixel electrode 210. For example, the peripheral pixel electrode 250 around (e.g., surrounding) the first main pixel electrode 211 and the peripheral pixel electrode 250 around (e.g., surrounding) the second main pixel electrode 212 may be spaced and/or apart (e.g., spaced apart or separated) from each other.

The display apparatus according to one or more embodiments may apply electrical signals from an external device to the main pixel electrode 210 and the peripheral pixel electrode 250, which respectively have the structures described above. Although described in more detail later, an emission layer (see, e.g., 220 of FIG. 5) may be formed by discharging, through an inkjet process, an emission layer forming material into the opening 120OP of the bank layer 120 and then drying the emission layer forming material through a drying process. At this time, in the drying process, a convection phenomenon is caused in an intermediate layer forming material by applying electrical signals to the main pixel electrode 210 and the peripheral pixel electrode 250, and thus, the emission layer (see, e.g., 220 of FIG. 5) may be formed to have a substantially uniform thickness.

Accordingly, the display apparatus according to one or more embodiments may further include a connection wire that electrically connects each of the main pixel electrode 210 and the peripheral pixel electrode 250 to an external device that applies an electrical signal thereto. The connection wire may include a first connection wire CW1 that connects the main pixel electrode 210 to the external device, and a second connection wire that connects the peripheral pixel electrode 250 to the external device. In one or more embodiments, the peripheral pixel electrode 250 is integrally formed on the substrate (see, e.g., 100 of FIG. 5), and thus, the peripheral pixel electrode 250 may be formed on the outside of the display apparatus. For example, the second connection wire may be formed on a non-display area (see, e.g., NDA of FIG. 1).

In a plan view, because the main pixel electrode 210 is surrounded by the peripheral pixel electrodes 250, the first connection wire CW1, which has to be connected to and extend from the main pixel electrode 210, may be on a layer that is different from a layer that the main pixel electrode 210 is on. For example, the first connection wire CW1 may be below the main pixel electrode 210 and the peripheral pixel electrode 250.

The first connection wire CW1 may extend in a first direction (e.g., a y direction) so as to connect the main pixel electrode 210 to the external device. At this time, the first connection wire CW1 may be connected to only one main pixel electrode 210, and may also be electrically connected to a plurality of main pixel electrodes 210 arranged with each other along (e.g., in a row in) the first direction (e.g., the y direction). For example, as illustrated in FIG. 4, the first connection wire CW1 may include a first-1 connection wire CW11, a first-2 connection wire CW12, and a first-3 connection wire CW13. The first-1 connection wire CW11 may be electrically connected to the main pixel electrodes 210 respectively corresponding to a plurality of first pixels PX1 and PX1′ arranged in the first direction (e.g., the y direction). Similarly, the first-2 connection wire CW12 may be electrically connected to the main pixel electrodes 210 respectively corresponding to a plurality of second pixels PX2 and PX2′ arranged in the first direction (e.g., the y direction), and the first-3 connection wire CW13 may be electrically connected to the main pixel electrodes 210 respectively corresponding to a plurality of third pixels PX3 and PX3′ arranged in the first direction (e.g., the y direction).

At this time, electrical signals of the same potential may be applied to the main pixel electrodes 210 connected to the first connection wire CW1. Because the peripheral pixel electrodes 250 are integrally formed with each other, the peripheral pixel electrodes 250 may receive electrical signals of the same potential on the entire surface of the substrate (see, e.g., 100 of FIG. 5) through the second connection wire.

However, the first connection wire CW1 may be disconnected within the display apparatus (see, e.g., 1 of FIG. 5). This is because, after connecting the external device to the main pixel electrode 210 in the drying process and transmitting an electrical signal thereto, the external device and the main pixel electrode 210 are disconnected if (e.g., when) the drying process is completed. In one or more embodiments, the first connection wire CW1 may be disconnected within the non-display area (see, e.g., NDA of FIG. 1) of the display apparatus (see, e.g., 1 of FIG. 1). However, the present disclosure is not limited thereto. The first connection wire CW1 may be disconnected in an area between the pixels (see, e.g., PX of FIG. 1) even within the display area (see, e.g., DA of FIG. 1). In addition, like the first connection wire CW1, the second connection wire that connects the peripheral pixel electrode 250 to the external device may be disconnected within the display apparatus (see, e.g., 1 of FIG. 5).

FIG. 5 is a schematic cross-sectional view of the display apparatus of FIG. 4 taken along the line I-I′ of FIG. 4.

Referring to FIG. 5, a pixel circuit layer PCL may be on a substrate 100. The pixel circuit layer PCL may include first and second transistors TR1 and TR2 and may include a buffer layer 111, a first gate insulating layer 113, a second gate insulating layer 115, an interlayer insulating layer 117, and a planarization layer 119, which are below and/or above the components of the first and second transistors TR1 and TR2. Each of the first and second transistors TR1 and TR2 may correspond to the first thin-film transistor T1 illustrated in FIG. 2. Because the structure of the second transistor TR2 is the same as or similar to the structure of the first transistor TR1, a redundant description thereof is not provided.

The buffer layer 111 may include an inorganic insulating material, such as silicon nitride (SiNₓ), silicon oxynitride (SiON), or silicon oxide (SiOₓ), and may have a single-layer structure or a multilayer structure including the inorganic insulating material described above. The buffer layer 111 may increase the smoothness of the top surface of the substrate 100 or may prevent, minimize, or reduce infiltration of impurities from the substrate 100 and/or the like into a semiconductor layer Act.

The first transistor TR1 may include a semiconductor layer Act, and the semiconductor layer Act may include polysilicon. In one or more embodiments, the semiconductor layer Act may include amorphous silicon, an oxide semiconductor material, or an organic semiconductor material.

A gate electrode GE may overlap a portion of the semiconductor layer Act. The gate electrode GE may include a conductive material. For example, the gate electrode GE may include a conductive material, such as molybdenum (Mo), aluminum (Al), or titanium (Ti), and may have a single-layer structure or a multilayer structure including the conductive material described above.

The first gate insulating layer 113 between the semiconductor layer Act and the gate electrode GE may include an inorganic insulating material, such as silicon oxide (SiO_{x (e.g., 2)}), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂).

The second gate insulating layer 115 may be to cover the gate electrode GE. Similar to the first gate insulating layer 113, the second gate insulating layer 115 may include an inorganic insulating material, such as silicon oxide (SiOₓ), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂).

An upper electrode CE2 of a storage capacitor Cst may be on the second gate insulating layer 115. The upper electrode CE2 may overlap the gate electrode GE thereunder. In this case, the gate electrode GE and the upper electrode CE2 that overlap each other with the second gate insulating layer 115 therebetween may constitute the storage capacitor Cst. For example, the gate electrode GE may function as a lower electrode CE1 of the storage capacitor Cst.

As described above, the storage capacitor Cst may be to overlap the first transistor TR1. In one or more embodiments, the storage capacitor Cst may be not to overlap the first transistor TR1.

The upper electrode CE2 may include a conductive material, such as aluminum (AI), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), or copper (Cu), and may have a single-layer structure or a multilayer structure including the conductive material described above.

The interlayer insulating layer 117 may cover the upper electrode CE2. The interlayer insulating layer 117 may include an inorganic insulating material, such as silicon oxide (SiO_{x (e.g., 2)}), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂). The interlayer insulating layer 117 may include a single-layer structure or a multilayer structure including the inorganic insulating material described above.

A drain electrode SD1 and a source electrode SD2 may be on the interlayer insulating layer 117. The drain electrode SD1 and the source electrode SD2 may be respectively electrically connected to the semiconductor layer Act through contact holes provided in the first gate insulating layer 113, the second gate insulating layer 115, and the interlayer insulating layer 117. Each of the drain electrode SD1 and the source electrode SD2 may include a material having good or suitable conductivity. Each of the drain electrode SD1 and the source electrode SD2 may include a conductive material including molybdenum (Mo), aluminum (AI), copper (Cu), or titanium (Ti), and/or the like and may include a single-layer structure or a multilayer structure including the conductive material described above. In one or more embodiments, each of the drain electrode SD1 and the source electrode SD2 may have a multilayer structure of Ti/Al/Ti. In one or more embodiments, one of the drain electrode SD1 and the source electrode SD2 may not be provided, and a portion of the semiconductor layer Act may be made conductive to replace the one of the drain electrode SD1 and the source electrode SD2 that is not provided.

In one or more embodiments, a first connection wire CW1 may be on the interlayer insulating layer 117. As described above, the first connection wire CW1 may electrically connect a main pixel electrode 210 to an external device that applies an electrical signal thereto. In one or more embodiments, the first connection wire CW1 may be connected to the main pixel electrode 210 through a contact hole of the planarization layer 119. For example, a first-1 connection wire CW11 may be electrically connected to a first main pixel electrode 211, and a first-2 connection wire CW12 may be electrically connected to a second main pixel electrode 212.

In one or more embodiments, the first connection wire CW1 may be arranged on the same layer as the drain electrode SD1 and the source electrode SD2 and may include the same material as a material of the drain electrode SD1 and the source electrode SD2. For example, the first connection wire CW1 may include a conductive material including molybdenum (Mo), aluminum (AI), copper (Cu), or titanium (Ti), and/or the like and may have a single-layer structure or a multilayer structure including the conductive material described above. However, the present disclosure is not limited thereto. When the planarization layer 119 to be described in more detail later includes a plurality of layers, the first connection wire CW1 may be between the planarization layers 119.

The planarization layer 119 may cover the first transistor TR1 and may include a contact hole exposing a portion of the first transistor TR1. The planarization layer 119 may include an organic insulating material. The planarization layer 119 may include an organic insulating material, for example, general-purpose polymer such as polymethylmethacrylate (PMMA) or polystyrene (PS), polymer derivatives having a phenolic group, acrylic polymer, imide-based polymer, aryl ether-based polymer, amide-based polymer, fluorine-based polymer, p-xylene-based polymer, vinyl alcohol-based polymer, and/or any blend or combination thereof.

A display element layer DEL may be on the pixel circuit layer PCL. The display element layer DEL may include first and second light-emitting diodes ED1 and ED2, and a bank layer 120 below and/or above the components of the first and second light-emitting diodes ED1 and ED2. In one or more embodiments, each of the first light-emitting diode ED1 and the second light-emitting diode ED2 may be a quantum dot light-emitting device. For example, each of the first light-emitting diode ED1 and the second light-emitting diode ED2 may have an emission layer including quantum dots. However, the present disclosure is not limited thereto. In one or more embodiments, each of the first light-emitting diode ED1 and the second light-emitting diode ED2 may be an organic light-emitting device. For example, each of the first light-emitting diode ED1 and the second light-emitting diode ED2 may have an emission layer that does not include quantum dots but includes only an organic material.

Each of the first light-emitting diode ED1 and the second light-emitting diode ED2 may include the main pixel electrode 210. The main pixel electrode 210 may include the first main pixel electrode 211 constituting the first light-emitting diode ED1 and the second main pixel electrode 212 constituting the second light-emitting diode ED2. The first main pixel electrode 211 and the second main pixel electrode 212 may be on the planarization layer 119 of the pixel circuit layer PCL. The first main pixel electrode 211 may be electrically connected to the drain electrode SD1 or the source electrode SD2 of the first transistor TR1 through a contact hole passing through the planarization layer 119. Similarly, the second main pixel electrode 212 may be electrically connected to the second transistor TR2 through a contact hole passing through the planarization layer 119.

The main pixel electrode 210 may be a reflective electrode, a transflective electrode, or a transmissive electrode. In order to form the main pixel electrode 210 as a transmissive electrode, indium tin oxide (ITO), indium zinc oxide (IZO), tin oxide (SnO₂), zinc oxide (ZnO), or any combination thereof may be used as a material for the pixel electrode. In order to form the main pixel electrode 210 as a transflective electrode or a reflective electrode, magnesium (Mg), silver (Ag), aluminum (AI), aluminum-lithium (Al—Li), calcium (Ca), magnesium-indium (Mg—In), magnesium-silver (Mg—Ag), or any combination thereof may be used as a material for the pixel electrode. The main pixel electrode 210 may have a single-layer structure consisting of a single layer or a multilayer structure including a plurality of layers. For example, the main pixel electrode 210 may have a three-layer structure of ITO/Ag/ITO.

As described above with reference to FIG. 4, the display apparatus 1 according to one or more embodiments may include a peripheral pixel electrode 250. The peripheral pixel electrode 250 may be spaced and/or apart (e.g., spaced apart or separated) from the main pixel electrode 210 by a certain distance in the second direction (e.g., the x direction) in a plan view of the display apparatus 1. For example, the peripheral pixel electrode 250 may be spaced and/or apart from the main pixel electrode 210 by a distance of about 5 μm to about 10 μm in the plan view of the display apparatus 1. The peripheral pixel electrode 250 may be around (e.g., may surround) the main pixel electrode 210 if (e.g., when) viewed from a direction normal (e.g., perpendicular) to the substrate 100 (e.g., when viewed the plan view of the display apparatus 1). The peripheral pixel electrode 250 may be between the main pixel electrodes 210 adjacent to each other. For example, the peripheral pixel electrode 250 may be between the first main pixel electrode 211 and the second main pixel electrode 212 and may be shared by the first pixel PX1 and the second pixel PX2.

In one or more embodiments, the peripheral pixel electrode 250 may be arranged on the same layer as the main pixel electrode 210. For example, the peripheral pixel electrode 250 and the main pixel electrode 210 are on the same layer. For example, the peripheral pixel electrode 250 may be on the planarization layer 119. The peripheral pixel electrode 250 may include the same material as a material of the main pixel electrode 210. For example, the peripheral pixel electrode 250 and the main pixel electrode 210 may include the same material. Accordingly, the peripheral pixel electrode 250 may be a reflective electrode, a transflective electrode, or a transmissive electrode. When the peripheral pixel electrode 250 is formed as a transmissive electrode, the peripheral pixel electrode 250 may include indium tin oxide (ITO), indium zinc oxide (IZO), tin oxide (SnO₂), zinc oxide (ZnO), or any combination thereof. When the peripheral pixel electrode 250 is formed as a reflective electrode or a transflective electrode, the peripheral pixel electrode 250 may include magnesium (Mg), silver (Ag), aluminum (AI), aluminum-lithium (Al—Li), calcium (Ca), magnesium-indium (Mg—In), magnesium-silver (Mg—Ag), or any combination thereof. However, the present disclosure is not limited thereto. The peripheral pixel electrode 250 may include a material that is different from a material of the main pixel electrode 210. For example, the peripheral pixel electrode 250 and the main pixel electrode 210 include a different material from each other.

The bank layer 120 may be on the planarization layer 119 of the pixel circuit layer PCL. The bank layer 120 may cover the edges of the first main pixel electrode 211 and the second main pixel electrode 212. For example, the bank layer 120 may be in contact with the top and side surfaces of the end of the main pixel electrode 210. In addition, because the peripheral pixel electrode 250 is between the main pixel electrodes 210 adjacent to each other, the bank layer 120 may be on the peripheral pixel electrode 250. The bank layer 120 may cover the top surface of the peripheral pixel electrode 250 and both (e.g., simultaneously) ends of the peripheral pixel electrode 250. As illustrated in FIG. 5, the bank layer 120 may insulate the main pixel electrode 210 and the peripheral pixel electrode 250 from each other.

The bank layer 120 may include one or more suitable materials. In one or more embodiments, the bank layer 120 may include an organic material, such as acrylic, benzocyclobutene (BCB), or hexamethyldisiloxane (HMDSO). In one or more embodiments, the bank layer 120 may include photoresist, that is, photosensitive resin. For example, the bank layer 120 may include a negative-type or kind photoresist that undergoes reaction such as crosslinking upon light exposure.

The bank layer 120 may define a first opening 120OP1 exposing the central portion of the first main pixel electrode 211 and a second opening 120OP2 exposing the central portion of the second main pixel electrode 212. For example, the bank layer 120 may define an emission area of the first light-emitting diode ED1 and an emission area of the second light-emitting diode ED2. The bank layer 120 may prevent or reduce an electric arc and/or the like from occurring on the edges of the main pixel electrodes 210 by increasing the distance between the edges of the main pixel electrodes 210 and the opposite electrode 230.

The intermediate layer may be located within the opening 120OP of the bank layer 120. The intermediate layer included in the light-emitting diode may include an emission layer 220. The emission layer 220 may include a first emission layer 221 constituting the first light-emitting diode ED1 and a second emission layer 222 constituting the second light-emitting diode ED2. For example, the first emission layer 221 may be on the first main pixel electrode 211 and located within the first opening 120OP1. Similarly, the second emission layer 222 may be on the second main pixel electrode 212 and located within the second opening 120OP2.

In one or more embodiments, the emission layer 220 may include quantum dot(s). For example, the quantum dot(s) included in the emission layer 220 may function as a dopant, and the emission layer 220 may further include a host and/or a delayed fluorescent material. The quantum dots refer to crystals of semiconductor compounds. The quantum dots may be configured to emit light of one or more suitable emission wavelengths depending on the size of the crystal. The quantum dots may be configured to emit light of one or more suitable emission wavelengths by controlling a ratio of elements constituting the quantum dots. For example, the diameter of the quantum dots may be about 1 nm to about 10 nm. In the present disclosure, when quantum dot, quantum dots, or quantum dot particles are spherical, “diameter” indicates a particle diameter or an average particle diameter, and when the particles are non-spherical, the “diameter” indicates a major axis length or an average major axis length. The diameter of the particles may be measured utilizing a scanning electron microscope or a particle size analyzer. As the particle size analyzer, for example, HORIBA, LA-950 laser particle size analyzer, may be utilized. When the size of the particles is measured utilizing a particle size analyzer, the average particle diameter is referred to as D50. D50 refers to the average diameter of particles whose cumulative volume corresponds to 50 vol % in the particle size distribution (e.g., cumulative distribution), and refers to the value of the particle size corresponding to 50% from the smallest particle when the total number of particles is 100% in the distribution curve accumulated in the order of the smallest particle size to the largest particle size.

The quantum dots may be synthesized by a wet chemical process, an organometallic chemical vapor deposition process, a molecular beam epitaxy process, or other processes similar thereto. The wet chemical process is a method of growing quantum dot particle crystals after mixing an organic solvent with a precursor material. When crystals grow, the organic solvent naturally acts as a dispersant coordinated to the surfaces of the quantum dot crystals and regulates the growth of the crystals. Accordingly, the wet chemical process is easier to perform than vapor deposition methods, such as metal organic chemical vapor deposition (MOCVD) or molecular beam epitaxy (MBE), and the growth of quantum dot particles may be controlled or selected through a low-cost process.

The quantum dots may include Group II-VI semiconductor compounds, Group III-V semiconductor compounds, Group III-VI semiconductor compounds, Group I-III-VI semiconductor compounds, Group IV-VI semiconductor compounds, Group IV elements or compounds, or any combination thereof.

Examples of the Group II-VI semiconductor compounds may include binary compounds, such as CdS, CdSe, CdTe, ZnS, ZnSe, ZnTe, ZnO, HgS, HgSe, HgTe, MgSe, or MgS, ternary compounds, such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, or MgZnS, quaternary compounds, such as CdZnSeS, CdZnSeTe, CdZnSTe, CdHgSeS, CdHgSeTe, CdHgSTe, HgZnSeS, HgZnSeTe, or HgZnSTe, or any combination thereof.

Examples of the Group III-V semiconductor compounds may include binary compounds, such as GaN, GaP, GaAs, GaSb, AlN, AIP, AIAs, AISb, InN, InP, InAs, or InSb, ternary compounds, such as GaNP, GaNAs, GaNSb, GaPAs, GaPSb, AlNP, AlNAs, AlNSb, AIPAs, AIPSb, InGaP, InNP, InAIP, InNAs, InNSb, InPAs, or InPSb, quaternary compounds, such as GaAINP, GaAINAs, GaAINSb, GaAIPAs, GaAIPSb, GalnNP, GalnNAs, GalnNSb, GalnPAs, GalnPSb, InAINP, InAINAs, InAINSb, InAIPAs, or InAIPSb, and any combination thereof. In one or more embodiments, the Group III-V semiconductor compounds may further include Group II elements. Examples of the Group III-V semiconductor compounds that further include the Group II elements may include InZnP, InGaZnP, or InAIZnP.

Examples of the Group III-VI semiconductor compounds may include binary compounds, such as GaS, Ga2S3, GaSe, GazSes, GaTe, InS, InSe, In₂S₃, In₂Se₃, or InTe, ternary compounds, such as InGaSs or InGaSes, or any combination thereof.

Examples of the Group I-III-VI semiconductor compounds may include ternary compounds, such as AgInS, AgInS₂, AgInSe₂, AgGaS, AgGaS₂, AgGaSe₂, CulnS, CulnS₂, CulnSe₂, CuGaS₂, CuGaSe₂, CuGaO₂, AgGaO₂, or AgAIO₂, quaternary compounds, such as AgInGaS₂, AgInGaSe₂, or CulnGaS, or any combination thereof.

Examples of the Group IV-VI semiconductor compounds may include binary compounds, such as SnS, SnSe, SnTe, PbS, PbSe, or PbTe, ternary compounds, such as SnSeS, SnSeTe, SnSTe, PbSeS, PbSeTe, PbSTe, SnPbS, SnPbSe, or SnPbTe, quaternary compounds, such as SnPbSSe, SnPbSeTe, or SnPbSTe, or any combination thereof.

Examples of the Group IV elements or compounds may include monatomic compounds, such as Si or Ge, binary compounds, such as SiC or SiGe, or any combination thereof.

Each of the elements included in the polyatomic compounds, such as the binary compounds, the ternary compounds, and the quaternary compounds, may be present in the particles at a substantially uniform concentration or a substantially non-uniform concentration. For example, the aforementioned formulae refer to the type or kind of elements included in the compounds, and the ratios of the elements within the compounds may be different. For example, AgInGaS₂ may refer to AgInₓGa₁₋ₓS₂ (x is a real number between 0 and 1).

In one or more embodiments, the quantum dots may have a single structure or a core-shell dual structure in which the concentration of each of the elements included in the quantum dots is substantially uniform. For example, a material included in the core may be different from a material included in the shell. The shell may cover at least a portion of the core.

The core may include Cd, Zn, Hg, Mg, Ga, Al, In, Sn, Pb, Se, Te, P, or Sb.

The shell of the quantum dot may act as a protective layer that maintains semiconductor properties by preventing or reducing chemical modification of the core and/or a charging layer that imparts electrophoretic properties to the quantum dot. The shell may be single-layer or layers. An interface between the core and the shell may have a concentration gradient in which the concentration of the element present in the shell decreases toward the center thereof.

Examples of the shell of the quantum dot may include metal or non-metal oxides, semiconductor compounds, or any combination thereof. Examples of the metal or non-metal oxides may include binary compounds, such as SiO₂, Al₂O₃, TiO₂, ZnO, MnO, Mn₂O₃, Mn₃O₄, CuO, FeO, Fe₂O₃, Fe₃O₄, CoO, Co₃O₄, or NiO, ternary compounds, such as MgAl₂O₄, CoFe₂O₄, NiFe₂O₄, or CoMn₂O₄, or any combination thereof. As described above, examples of the semiconductor compounds may include Group III-VI semiconductor compounds, Group II-VI semiconductor compounds, Group III-V semiconductor compounds, Group III-VI semiconductor compounds, Group I-III-VI semiconductor compounds, Group IV-VI semiconductor compounds, or any combination thereof. Examples of the semiconductor compounds may include CdS, CdSe, CdTe, ZnS, ZnSe, ZnTe, ZnSeS, ZnTeS, GaAs, GaP, GaS, GaSe, AgGaS, AgGaS₂, GaSb, HgS, HgSe, HgTe, InAs, InP, InGaP, InSb, AlAs, AIP, AISb, or any combination thereof.

Each of the elements included in the polyatomic compounds, such as the binary compounds, the ternary compounds, and the quaternary compounds, may be present in the particles at a substantially uniform concentration or a substantially non-uniform concentration. For example, the aforementioned formulae refer to the type or kind of elements included in the compounds, and the ratios of elements within the compounds may be different.

The quantum dots may have a full width at half maximum (FWHM) of an emission wavelength spectrum in a range of about 45 nm or less, specifically about 40 nm or less, and more specifically about 30 nm or less. In this range, color purity or color reproducibility may be improved. Because light emitted from the quantum dots is emitted in all directions, a viewing angle may be improved.

In addition, as the quantum dots, spherical, pyramidal, multi-arm, or cubic nanoparticles, nanotubes, nanowires, nanofibers, or nanoplatelet particles may be used.

Because the energy band gap may be controlled or selected by adjusting the size of the quantum dots or the ratios of elements within the quantum dot compounds, light of one or more suitable wavelengths may be obtained from the quantum dot emission layer. Therefore, a light-emitting device that is configured to emit light of one or more suitable wavelengths may be implemented by using quantum dots as described above (using quantum dots having different sizes or having different ratios of elements within the quantum dot compounds). For example, the sizes of the quantum dots or the ratios of elements within the quantum dot compounds may be selected to emit red light, green light, and/or blue light. In addition, the quantum dots may be configured to emit white light by combining light of one or more suitable colors.

In one or more embodiments, the emission layer 220 may be an emission layer including only an organic material (e.g., does not include quantum dots). In this case, the emission layer 220 may include an organic material including a fluorescent or phosphorescent material that is configured to emit red light, green light, blue light, or white light. The emission layer 220 may be an organic emission layer including a low molecular weight organic material or a high molecular weight organic material. For example, if (e.g., when) the emission layer 220 is an organic emission layer, the emission layer 220 may include copper phthalocyanine, tris-8-hydroxyquinoline aluminum, a poly-phenylenevinylene (PPV)-based material, or a polyfluorene-based material.

However, the present disclosure is not limited thereto. The emission layer 220 may partially include quantum dots and partially include only an organic material. For example, the first emission layer 221 configured to emit red light and the second emission layer 222 configured to emit green light may each include quantum dots, and the emission layer of the third pixel (see, e.g., PX3 of FIG. 4) configured to emit blue light may include only an organic material (e.g., the emission layer of the third pixel configured to emit blue light does not include quantum dots (e.g., does not include any quantum dot)).

In one or more embodiments, the intermediate layer may further include a common layer between the pixel electrode 210 and the emission layer 220 and/or between the emission layer 220 and the opposite electrode 230. Hereinafter, the common layer between the pixel electrode 210 and the emission layer 220 may be referred to as a first common layer, and the common layer between the emission layer 220 and the opposite electrode 230 may be referred to as a second common layer. Each of the first common layer and the second common layer may include an organic material.

The first common layer is a hole transport region and may include a hole injection layer, a hole transport layer, an emission auxiliary layer, an electron blocking layer, or any combination thereof. For example, the first common layer may have a multilayer structure of a hole injection layer/a hole transport layer, a hole injection layer/a hole transport layer/an emission auxiliary layer, a hole injection layer/an emission auxiliary layer, a hole transport layer/an emission auxiliary layer, or a hole injection layer/a hole transport layer/an electron blocking layer, which are sequentially stacked in this stated order from the pixel electrode 210.

The second common layer is an electron transport region and may include a buffer layer, a hole blocking layer, an electron control layer, an electron transport layer, an electron injection layer, or any combination thereof. For example, the electron transport region may have a structure of an electron transport layer/an electron injection layer, a hole blocking layer/an electron transport layer/an electron injection layer, an electron control layer/an electron transport layer/an electron injection layer, or a buffer layer/an electron transport layer/an electron injection layer, which are sequentially stacked in this stated order from the emission layer 220.

The opposite electrode 230 may be to cover the emission layer 220 and the bank layer 120. For example, the opposite electrode 230 may be integrally formed across the entire surface of the substrate 100 so as to cover the first emission layer 221 and the second emission layer 222. For example, the opposite electrode 230 may overlap the emission layer 220 and the bank layer 120 in a plan view of the display apparatus 1. As a material for the opposite electrode 230, a metal, an alloy, an electrically conductive compound, or any combination thereof, which each has a low work function, may be used. The opposite electrode 230 may include lithium (Li), silver (Ag), magnesium (Mg), aluminum (AI), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or any combination thereof. The opposite electrode 230 may be a transmissive electrode, a transflective electrode, or a reflective electrode. The opposite electrode 230 may have a single-layer structure consisting of a single layer or a multilayer structure including a plurality of layers.

In one or more embodiments, in the first light-emitting diode ED1 and the second light-emitting diode ED2 respectively having the structures described above, the intermediate layer, specifically the emission layer 220, may be formed to have a substantially uniform thickness. In addition, the thickness uniformity of the emission layer 220 affects the light emission efficiency and lifespan efficiency of the light-emitting diode. Accordingly, the display apparatus according to one or more embodiments may improve the light emission efficiency and lifespan efficiency of the light-emitting diode.

The emission layer 220 may be formed by discharging, through an inkjet process, an emission layer forming material into the opening 120OP of the bank layer 120 and then drying the emission layer forming material through a drying process. At this time, capillary flow and Marangoni flow may occur within the emission layer forming material due to the difference in evaporation rate and/or surface tension during the drying process. In general, because a liquid is dried from the edge, a liquid located inside the emission layer forming material flows to the edge due to capillary flow. For example, the liquid tends to maintain a spherical shape due to surface tension, and thus, if (e.g., when) the edge portion of the liquid evaporates first, the liquid inside the emission layer forming material may flow to the edge and move so as to maintain an original shape as much as possible. However, if (e.g., when) the emission layer forming material flows to the edge, the surface tension of the central portion of the emission layer forming material decreases. Accordingly, a solute may move back toward the center of the emission layer forming material on the surface of the emission layer forming material due to Marangoni flow. For example, capillary flow and Marangoni phenomenon may occur in a complex manner within the emission layer forming material.

In one or more embodiments, capillary flow may be stronger than Marangoni flow according to the characteristics of the emission layer forming material itself or the drying environment. When capillary flow is stronger than Marangoni flow, the solute that has moved from the inside of the emission layer forming material accumulates at the edge and the solute may continue to accumulate as the liquid continues to evaporate. As described above, the phenomenon in which the solute is pushed out by the solvent due to the difference in evaporation rate and piles up in a ring shape from the outside may be referred to as a coffee ring effect. The emission layer 220 may be dried to have a U-shape with a central portion deeply recessed due to the coffee ring effect. For example, if (e.g., when) capillary flow is stronger than Marangoni flow, the thickness of the emission layer 220 may become substantially non-uniform, which may deteriorate the characteristics of the light-emitting diode.

At this time, in the display apparatus 1 according to one or more embodiments, the emission layer 220 may be formed to have a substantially uniform thickness by applying electrical signals to the main pixel electrode 210 and the peripheral pixel electrode 250 during the drying process. For example, the main pixel electrode 210 may be connected to the external device through the first connection wire CW1 and the peripheral pixel electrode 250 may be connected to the external device through the second connection wire, so that the main pixel electrode 210 and the peripheral pixel electrode 250 may receive alternating current signals.

When the alternating current signals are applied to the main pixel electrode 210 and the peripheral pixel electrode 250 during the drying process, the flow of the emission layer forming material may be caused by an alternating-current electro-osmosis (ACEO) phenomenon. In the ACEO phenomenon, the solvent moves on two electrodes forming an electric field in an opposite direction to a direction in which the electrodes face each other, and thus, the flow is caused. Accordingly, if (e.g., when) the electric field is formed by applying the alternating current signals to the main pixel electrode 210 and the peripheral pixel electrode 250 respectively having the structures described above, the flow in which the solvent moves from the edge to the center region within the emission layer 220 may occur.

Consequently, in a case where capillary flow in which the solvent moves to the edge is stronger than Marangoni flow, if (e.g., when) electrical signals are applied to the main pixel electrode 210 and the peripheral pixel electrode 250 each having the structure illustrated in FIG. 5, capillary flow may be alleviated by ACEO. Accordingly, in the display apparatus 1 according to one or more embodiments, because the emission layer forming material balances capillary flow and Marangoni flow during the drying process, the emission layer 220 may be formed to have a substantially uniform thickness.

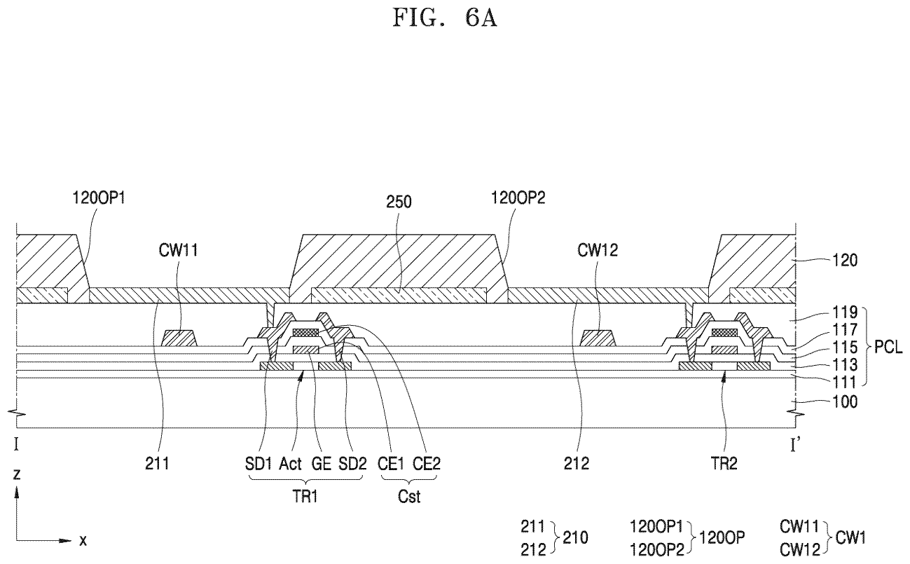

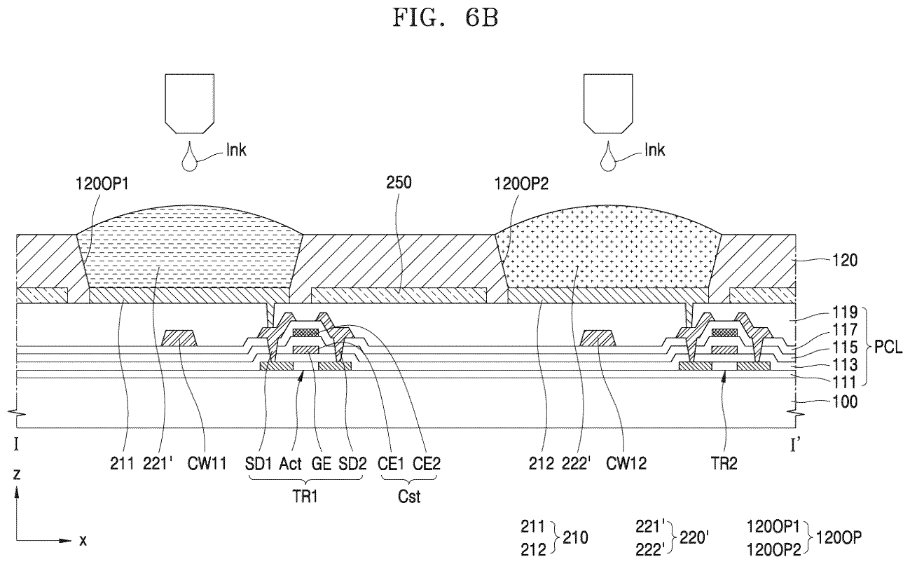

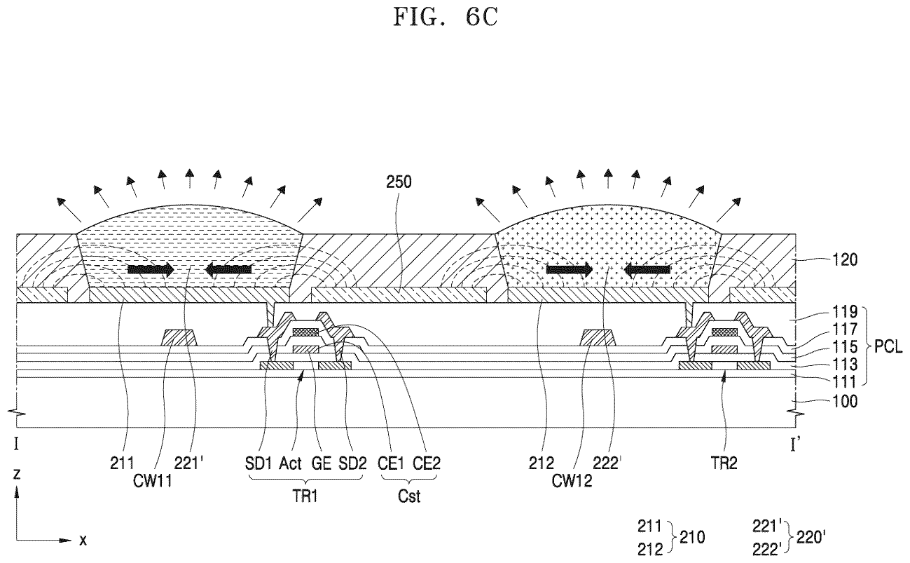

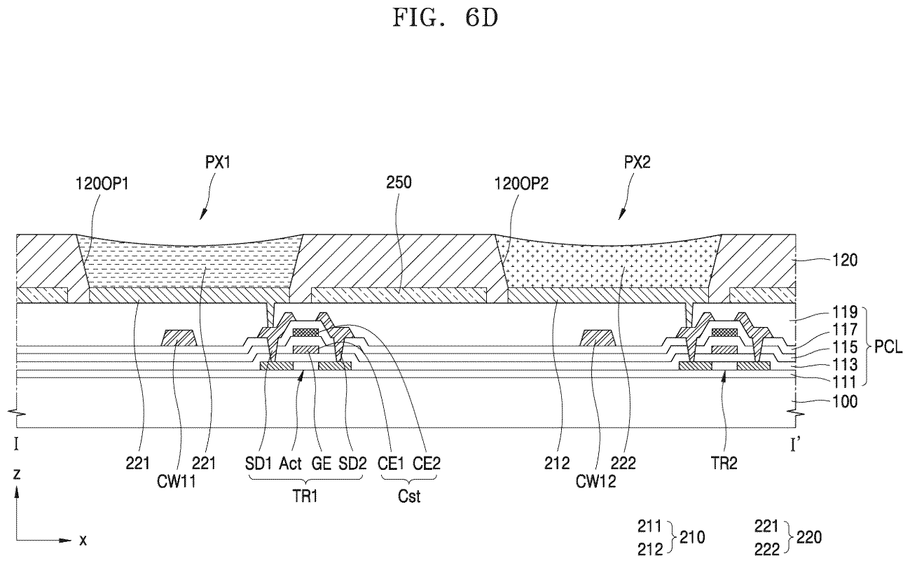

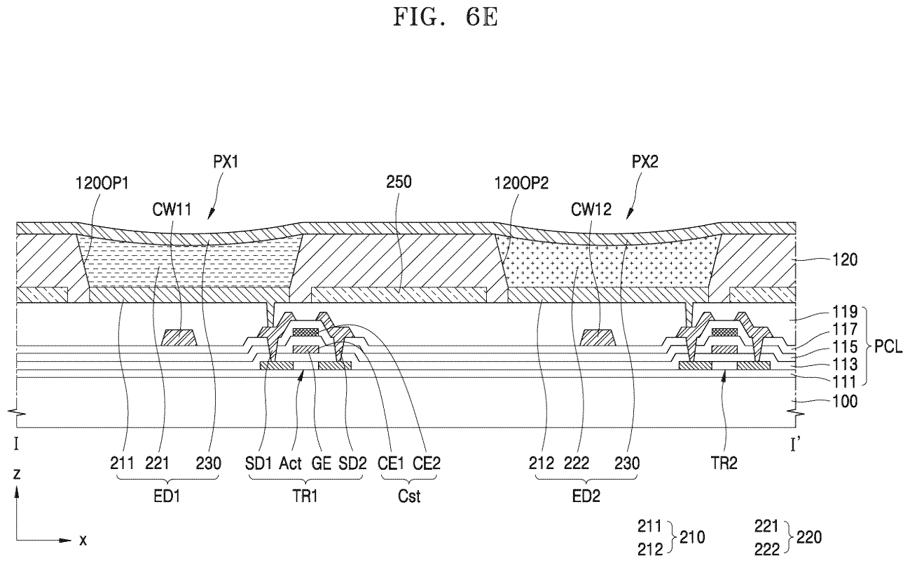

FIGS. 6A to 6E are cross-sectional views schematically illustrating a method of manufacturing a display apparatus, according to one or more embodiments. FIGS. 6A to 6E are cross-sectional views of the display apparatus of FIG. 4 taken along the line I-I′ according to the manufacturing process.

Referring to FIG. 6A, a pixel circuit layer PCL may be formed on a substrate 100, and a main pixel electrode 210 and a peripheral pixel electrode 250 may be formed on the pixel circuit layer PCL.

For example, a first main pixel electrode 211 corresponding to a first pixel (see, e.g., PX1 of FIG. 5) and a second main pixel electrode 212 corresponding to a second pixel (see, e.g., PX2 of FIG. 5) may be formed on a planarization layer 119. The peripheral pixel electrode 250 may be spaced and/or apart (e.g., spaced apart or separated) from the main pixel electrode 210 and may be formed to be around (e.g., surround) the main pixel electrode 210.

The peripheral pixel electrode 250 may be formed on the same layer as the main pixel electrode 210 and may include the same material as a material of the main pixel electrode 210. For example, the peripheral pixel electrode 250 and the main pixel electrode 210 may be formed on the same layer and may include the same material. Accordingly, the main pixel electrode 210 and the peripheral pixel electrode 250 may be concurrently (e.g., simultaneously) deposited through the same deposition process.

A bank layer 120 may be formed on the main pixel electrode 210 and the peripheral pixel electrode 250. The bank layer 120 may be formed to cover the end of the main pixel electrode 210 and the top surface of the peripheral pixel electrode 250. The bank layer 120 may be formed by forming an inorganic insulating material layer or an organic insulating material layer and then patterning an opening 120OP to expose the central portion of the main pixel electrode 210.

Referring to FIG. 6B, by discharging ink including an emission layer forming material, a first material layer 221′ may be formed in a first opening 120OP1 and a second material layer 222′ may be formed in a second opening 120OP2. The first material layer 221′ and the second material layer 222′ constitute a material layer 220′. For example, the first material layer 221′ may be formed on the first main pixel electrode 211, and the second material layer 222′ may be formed on the second main pixel electrode 212. In one or more embodiments, the material layer 220′ may include a light-emitting material including quantum dots.

In one or more embodiments, the material layer 220′ may be formed through an inkjet printing process. The material layer 220′ may have a convex shape with respect to the substrate 100 with a thick central portion, considering the surface tension and volume shrinkage after drying. However, the present disclosure is not limited thereto. In one or more embodiments, the material layer 220′ may have a flat shape or a concave shape with respect to the substrate 100 according to an injection amount of ink including a light-emitting material.

Referring to FIG. 6C, an emission layer (see, e.g., 220 of FIG. 6D) may be formed by drying the material layer 220′. However, as described above, a solvent of the ink including the light-emitting material evaporates. When a capillary flow phenomenon is strong, the emission layer (see, e.g., 220 of FIG. 6D) may have a U-shaped substantially non-uniform thickness.

Accordingly, in the method of manufacturing a display apparatus, according to one or more embodiments, electrical signals may be applied from an external device to the main pixel electrode 210 and the peripheral pixel electrode 250. An electrical signal may be transmitted to the first main pixel electrode 211 through a first-1 connection wire CW11, and an electrical signal may be transmitted to the second main pixel electrode 212 through a first-2 connection wire CW12. in one or more embodiments, the peripheral pixel electrode 250 may also receive an electrical signal from the external device through the second connection wire.

The peripheral pixel electrode 250 has a shape around (e.g., surrounding) the main pixel electrode 210. Accordingly, if (e.g., when) alternating current signals are applied to the main pixel electrode 210 and the peripheral pixel electrode 250, an electric field may be formed between the main pixel electrode 210 and the peripheral pixel electrode 250, and thus, the solvent in the material layer 220′ may move from the edge to the central portion due to an ACEO phenomenon. For example, as illustrated in FIG. 6C, the solvent in the material layer 220′ may move from the region adjacent to the bank layer 120 to the central portion of the main pixel electrode 210.

When the flow occurs in the direction described above, the effect due to capillary flow is weakened, and thus, the material layer 220′ may be dried to have a substantially uniform thickness. Consequently, the light emission efficiency and lifespan efficiency of the light-emitting diode may be improved through the method of manufacturing a display apparatus, according to one or more embodiments. At this time, after the drying process is completed, the first connection wire CW1 and the second connection wire may be disconnected within a non-display area (see, e.g., NDA1 of FIG. 1).

Referring to FIG. 6D, after the drying of the emission layer 220 is completed, a bake process may be additionally performed. As the emission layer 220 is heat-treated in a condition of about 140° C. to about 230° C., the density inside the emission layer 220 may be increased and the light emission efficiency may be improved.

Specific conditions, such as the temperature and time of the bake process, may be appropriately or suitably selected according to the type or kind and capacity of the material. However, the present disclosure is not limited thereto. In some cases, the bake process may not be provided.

Referring to FIG. 6E, an opposite electrode 230 may be formed on the emission layer 220 and the bank layer 120. The opposite electrode 230 may be integrally formed across the entire surface of the substrate 100. Accordingly, the first main pixel electrode 211, the first emission layer 221, and the opposite electrode 230 may constitute the first light-emitting diode ED1, and the second main pixel electrode 212, the second emission layer 222, and the opposite electrode 230 may constitute the second light-emitting diode ED2.

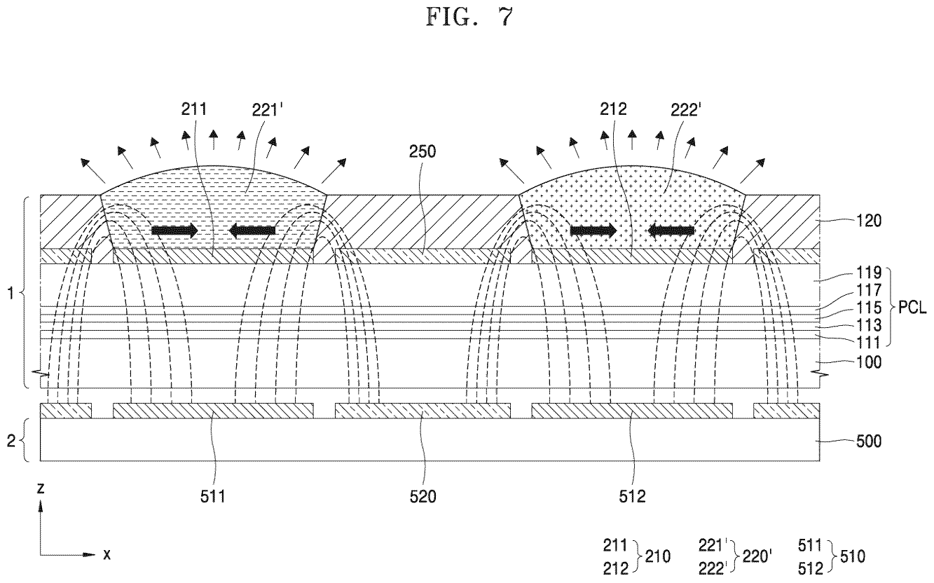

FIG. 7 is a cross-sectional view schematically illustrating a method of manufacturing a display apparatus, according to one or more embodiments. Referring to FIG. 7, other features except for a mobile device 2 may each independently be the same as described with reference to FIGS. 6A to 6E. In FIG. 7, the same reference numerals denote the same elements as those described with reference to FIGS. 6A to 6E and differences are mainly described in more detail later.

Referring to FIG. 7, an electric field may be formed by bringing the mobile device 2 close to the display apparatus 1. For example, the mobile device 2 may include an auxiliary substrate 500, a first auxiliary electrode 510, and a second auxiliary electrode 520.

Like the substrate 100, the auxiliary substrate 500 may include glass, metal, or polymer resin. Examples of the polymer resin may include polyethersulfone, polyacrylate, polyetherimide, polyethylene naphthalate, polyethylene terephthalate, polyphenylene sulfide, polyarylate, polyimide, polycarbonate, cellulose acetate propionate, or any mixture thereof. In one or more embodiments, other modifications are possible. For example, the auxiliary substrate 500 may have a multilayer structure that includes two layers and a barrier layer therebetween, wherein the two layers may include polymer resin and the barrier layer may include an inorganic material (e.g., silicon oxide (SiOₓ), silicon nitride (SiNₓ), silicon oxynitride (SiON), and/or the like).

However, in the case of the mobile device 2, a pixel circuit layer PCL, and/or the like may not be, and the first auxiliary electrode 510 and the second auxiliary electrode 520 may be deposited on the auxiliary substrate 500. The first auxiliary electrode 510 and the second auxiliary electrode 520 may include the same materials as materials of a main pixel electrode 210 and a peripheral pixel electrode 250 of the display apparatus 1. For example, the first auxiliary electrode 510, the second auxiliary electrode 520, the main pixel electrode 210, and the peripheral pixel electrode 250 include the same materials. For example, each of the first auxiliary electrode 510 and the second auxiliary electrode 520 may include conductive material capable of electric field induction.

In this case, the first auxiliary electrode 510 may be formed in substantially the same shape as a shape of the main pixel electrode 210 and may be formed to have the same area as a shape of the main pixel electrode 210. In addition, the first auxiliary electrode 510 may be formed at a position that may overlap the main pixel electrode 210 in a plan view of the display apparatus 1 if (e.g., when) the substrate 100 and the auxiliary substrate 500 are aligned with each other. For example, a first-1 auxiliary electrode 511 may be formed at the same position as a position of the first main pixel electrode 211 and may be formed to have the same area as an area of the first main pixel electrode 211, and a first-2 auxiliary electrode 512 may be formed at the same position as a position of the second main pixel electrode 212 and may be formed to have the same area as an area of the second main pixel electrode 212.

Similarly, the second auxiliary electrode 520 may be formed in substantially the same shape as a shape of the peripheral pixel electrode 250 and may be formed to have the same area as an area of the peripheral pixel electrode 250. In addition, the second auxiliary electrode 520 may be formed at a position that may overlap the peripheral pixel electrode 250 in a plan view of the display apparatus 1 if (e.g., when) the substrate 100 and the auxiliary substrate 500 are aligned with each other. Accordingly, the second auxiliary electrode 520 may be formed to be around (e.g., surround) the first auxiliary electrode 510 in a plan view and may be between the first-1 auxiliary electrode 511 and the first-2 auxiliary electrode 512.

At this time, in the method of manufacturing a display apparatus, according to one or more embodiments, in the process of drying the material layer 220′ so as to form the emission layer (see, e.g., 220 of FIG. 5), the mobile device 2 having the structure described above may be brought close to the display apparatus 1, and then, an external device that applies an electrical signal to the mobile device 2 may be connected to the mobile device 2. For example, by connecting the external device to the first auxiliary electrode 510 and the second auxiliary electrode 520 of the mobile device 2, alternating current signals may be applied to the first auxiliary electrode 510 and the second auxiliary electrode 520.

When the alternating current signals are applied to the first auxiliary electrode 510 and the second auxiliary electrode 520, an electric field may be formed between the first auxiliary electrode 510 and the second auxiliary electrode 520. As the mobile device 2 in which the electric field is formed is brought close to the display apparatus 1, the electric field formed between the first auxiliary electrode 510 and the second auxiliary electrode 520 may affect the material layer 220′. In particular, because the second auxiliary electrode 520 has a shape around (e.g., surrounding) the first auxiliary electrode 510, a solvent in the material layer 220′ may move from the edge to the central portion due to an ACEO phenomenon. For example, as illustrated in FIG. 7, the solvent in the material layer 220′ may move from the region adjacent to the bank layer 120 to the central portion of the main pixel electrode 210.

As illustrated in FIG. 7, if (e.g., when) the mobile device 2 is brought close to the display apparatus 1 and the flow occurs in the direction described above, the effect due to capillary flow may be weakened, and thus, the material layer 220′ may be dried to have a substantially uniform thickness. Consequently, the light emission efficiency and lifespan efficiency of the light-emitting diode may be improved through the method of manufacturing a display apparatus, according to one or more embodiments.

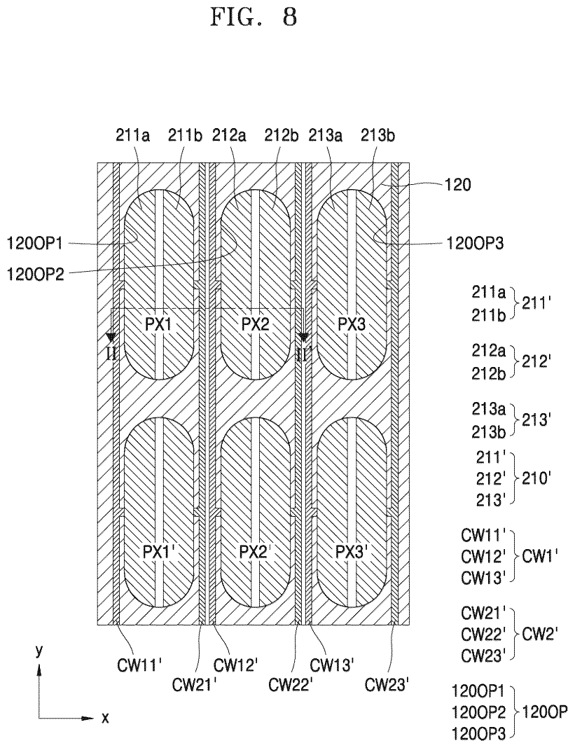

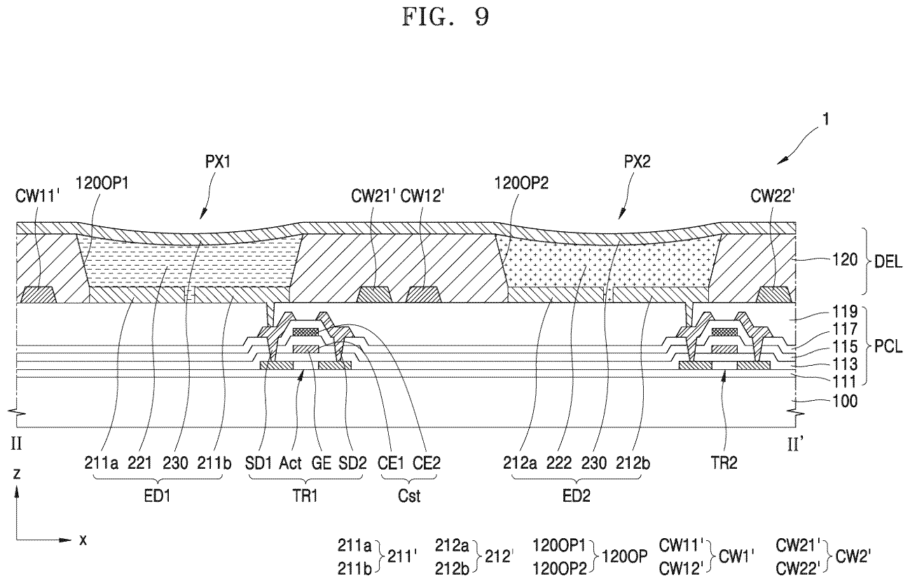

FIG. 8 is a schematic plan view of a display apparatus according to one or more embodiments. FIG. 9 is a schematic cross-sectional view of the display apparatus of FIG. 8 taken along the line II-II′ of FIG. 8. Referring to FIGS. 8 and 9, other features except for a pixel electrode 210′, a first connection wire CW1′, and a second connection wire CW2′ may each independently be the same as those described with reference to FIGS. 4 and 5. In FIGS. 8 and 9, the same reference numerals denote the same elements as those described with reference to FIGS. 4 and 5 and differences are mainly described in more detail.

Referring to FIG. 8, the pixel electrode 210′ may include a first pixel electrode 211′ corresponding to a first pixel PX1, a second pixel electrode 212′ corresponding to a second pixel PX2, and a third pixel electrode 213′ corresponding to a third pixel PX3.

In one or more embodiments, the pixel electrode 210′ may include two sub-pixel electrodes spaced and/or apart (e.g., spaced apart or separated) from each other. For example, the first pixel electrode 211′ may include a first sub-pixel electrode 211a and a second sub-pixel electrode 211b spaced and/or apart (e.g., spaced apart or separated) from the first sub-pixel electrode 211a. The second pixel electrode 212′ may include a third sub-pixel electrode 212a and a fourth sub-pixel electrode 212b spaced and/or apart (e.g., spaced apart or separated) from the third sub-pixel electrode 212a. Similarly, the third pixel electrode 213′ may include a fifth sub-pixel electrode 213a and a sixth sub-pixel electrode 213b spaced and/or apart (e.g., spaced apart or separated) from the fifth sub-pixel electrode 213a.

In one or more embodiments, the two sub-pixel electrodes spaced and/or apart (e.g., spaced apart or separated) from each other may have the same area and respectively have shapes that are symmetrical with each other. For example, the first sub-pixel electrode 211a and the second sub-pixel electrode 211b may have the same area and respectively have shapes that are symmetrical with each other. The third sub-pixel electrode 212a and the fourth sub-pixel electrode 212b may have the same area and respectively have shapes that are symmetrical with each other, and the fifth sub-pixel electrode 213a and the sixth sub-pixel electrode 213b may have the same area and respectively have shapes that are symmetrical with each other.

In addition, each of the two sub-pixel electrodes spaced and/or apart (e.g., spaced apart or separated) from each other may be connected to a pixel circuit corresponding to a relevant pixel. For example, the first sub-pixel electrode 211a and the second sub-pixel electrode 211b may be individually connected to a first transistor TR1.

A bank layer 120 may be on the pixel electrode 210′ and may cover the edges of each of the sub-pixel electrodes. For example, the bank layer 120 may have a first opening 120OP1 exposing the first sub-pixel electrode 211a and the second sub-pixel electrode 211b, a second opening 120OP2 exposing the third sub-pixel electrode 212a and the fourth sub-pixel electrode 212b, and a third opening 120OP3 exposing the fifth sub-pixel electrode 213a and the sixth sub-pixel electrode 213b. The opening 120OP of the bank layer 120 may expose the top surface of the sub-pixel electrode. In addition, as the two sub-pixel electrodes are spaced and/or apart (e.g., spaced apart or separated) from each other, the opening 120OP of the bank layer 120 may expose a partial region of a planarization layer (see, e.g., 119 of FIG. 9).

In one or more embodiments, the display apparatus 1 according to one or more embodiments may further include a connection wire that electrically connects each of the sub-pixel electrodes to an external device that applies an electrical signal. The connection wire may include a first connection wire CW1′ and a second connection wire CW2′ respectively configured to transmit electrical signals to the two sub-pixel electrodes corresponding to one pixel (see, e.g., PX of FIG. 1). For example, the first connection wire CW1′ may be configured to transmit an electrical signal to the sub-pixel electrode arranged on the left of the two sub-pixel electrodes with respect to the second direction (e.g., the x direction). The second connection wire CW2′ may be configured to transmit an electrical signal to the sub-pixel electrode arranged on the right of the two sub-pixel electrodes with respect to the second direction (e.g., the x direction). For example, a first-1 connection wire CW11′ may be electrically connected to the first sub-pixel electrode 211a, a first-2 connection wire CW12′ may be electrically connected to the third sub-pixel electrode 212a, and a first-3 connection wire CW13′ may be electrically connected to the fifth sub-pixel electrode 213a. A second-1 connection wire CW21′ may be electrically connected to the second sub-pixel electrode 211b, a second-2 connection wire CW22′ may be electrically connected to the fourth sub-pixel electrode 212b, and a second-3 connection wire CW23′ may be electrically connected to the sixth sub-pixel electrode 213b.

Each of the first connection wire CW1′ and the second connection wire CW2′ may extend in the first direction (e.g., the y direction) so as to connect the sub-pixel electrode to the external device. At this time, each of the first connection wire CW1′ and the second connection wire CW2′ may be connected to only one sub-pixel electrode and may also be electrically connected to a plurality of sub-pixel electrodes arranged with each other (e.g., in a row in) the first direction (e.g., the y direction). In this case, electrical signals of the same potential may be applied to the sub-pixel electrodes connected to the first connection wire CW1′, and electrical signals of the same potential may be applied to the sub-pixel electrodes connected to the second connection wire CW2′. For example, the first sub-pixel electrode 211a, the third sub-pixel electrode 212a, and the fifth sub-pixel electrode 213a may respectively receive electrical signals of the same potential, and the second sub-pixel electrode 211b, the fourth sub-pixel electrode 212b, and the sixth sub-pixel electrode 213b may respectively receive electrical signals of the same potential.

For example, the first connection wire CW1′ and the second connection wire CW2′ may be between the pixels (see, e.g., PX of FIG. 1) adjacent to each other. For example, two connection wires may be between the pixels (see, e.g., PX of FIG. 1) adjacent to each other.

However, the first connection wire CW1′ and the second connection wire CW2′ may be disconnected within the display apparatus 1. In one or more embodiments, the first connection wire CW1′ and the second connection wire CW2′ may be disconnected within a non-display area (see, e.g., NDA of FIG. 1).

Referring to FIG. 9, the first pixel electrode 211′ and the second pixel electrode 212′ may be on the planarization layer 119. As described above, the first pixel electrode 211′ may include the first sub-pixel electrode 211a and the second sub-pixel electrode 211b. The first sub-pixel electrode 211a and the second sub-pixel electrode 211b may be spaced and/or apart (e.g., spaced apart or separated) from each other by a certain distance. For example, the first sub-pixel electrode 211a and the second sub-pixel electrode 211b may be spaced and/or apart (e.g., spaced apart or separated) from each other by a distance of about 5 μm to about 10 μm.

The first sub-pixel electrode 211a and the second sub-pixel electrode 211b may be arranged on the same layer. The first sub-pixel electrode 211a and the second sub-pixel electrode 211b may have the same area and may include the same material. For example, each of the first sub-pixel electrode 211a and the second sub-pixel electrode 211b may be a reflective electrode, a transflective electrode, or a transmissive electrode. In order to form the first sub-pixel electrode 211a and the second sub-pixel electrode 211b as a transmissive electrode, indium tin oxide (ITO), indium zinc oxide (IZO), tin oxide (SnO₂), zinc oxide (ZnO), or any combination thereof may be used as a material for the pixel electrode. In order to form the first sub-pixel electrode 211a and the second sub-pixel electrode 211b as a transflective electrode or a reflective electrode, magnesium (Mg), silver (Ag), aluminum (AI), aluminum-lithium (Al—Li), calcium (Ca), magnesium-indium (Mg—In), magnesium-silver (Mg—Ag), or any combination thereof may be used as a material for the pixel electrode. Each of the first sub-pixel electrode 211a and the second sub-pixel electrode 211b may have a single-layer structure consisting of a single layer or a multilayer structure including a plurality of layers. For example, each of the first sub-pixel electrode 211a and the second sub-pixel electrode 211b may have a three-layer structure of ITO/Ag/ITO. The features of the first sub-pixel electrode 211a and the second sub-pixel electrode 211b may be equally applied to the third sub-pixel electrode 212a and the fourth sub-pixel electrode 212b.

In one or more embodiments, the first connection wire CW1′ and the second connection wire CW2′ may be on the planarization layer 119. For example, the first connection wire CW1′ and the second connection wire CW2′ may include the same materials as materials of the first sub-pixel electrode 211a and the second sub-pixel electrode 211b. For example, the first connection wire CW1′, the second connection wire CW2′, the first sub-pixel electrode 211a, and the second sub-pixel electrode 211b may include the same materials. For example, each of the first connection wire CW1′ and the second connection wire CW2′ may include indium tin oxide (ITO), indium zinc oxide (IZO), tin oxide (SnO₂), zinc oxide (ZnO), or any combination thereof, or may include magnesium (Mg), silver (Ag), aluminum (AI), aluminum-lithium (Al—Li), calcium (Ca), magnesium-indium (Mg—In), magnesium-silver (Mg—Ag), or any combination thereof. However, the present disclosure is not limited thereto. In one or more embodiments, the first connection wire CW1′ and the second connection wire CW2′ may be below the first pixel electrode 211. For example, the first connection wire CW1′ and the second connection wire CW2′ may be arranged on the same layer as a drain electrode SD1 and may include the same material as a material of the drain electrode SD1. For example, the first connection wire CW1′, the second connection wire CW2′, and the drain electrode SD1 may be arranged on the same layer and may include the same material.

A bank layer 120 may be on the planarization layer 119. The bank layer 120 may cover the edges of the first pixel electrode 211′ and the second pixel electrode 212′. For example, the bank layer 120 may cover the end of the first sub-pixel electrode 211a that does not face the second sub-pixel electrode 211b and may cover the end of the second sub-pixel electrode 211b that does not face the first sub-pixel electrode 211a. In addition, because the first connection wire CW1′ and the second connection wire CW2′ are between the pixel electrodes adjacent to each other, the bank layer 120 may cover the top surfaces of the first connection wire CW1′ and the second connection wire CW2′.

In the first light-emitting diode ED1 and the second light-emitting diode ED2 each having the structure described above, the intermediate layer, specifically the emission layer 220, may be formed to have a substantially uniform thickness. In addition, the thickness uniformity of the emission layer 220 affects the light emission efficiency and lifespan efficiency of the light-emitting diode. Accordingly, the display apparatus according to one or more embodiments may improve the light emission efficiency and lifespan efficiency of the light-emitting diode.

As described above, the emission layer 220 may be formed by discharging, through an inkjet process, an emission layer forming material into the opening 120OP of the bank layer 120 and then drying the emission layer forming material through a drying process. At this time, capillary flow and Marangoni flow may occur within the emission layer forming material.

In one or more embodiments, Marangoni flow may be stronger than capillary flow according to the characteristics of the emission layer forming material itself or the drying environment. When Marangoni flow is stronger than capillary flow, the solute that has moved from the edge accumulates at the central portion and the solute may continue to accumulate as the liquid continues to evaporate. For example, if (e.g., when) Marangoni flow is strong in the emission layer forming material, the emission layer 220 may be dried to have a W-shape with a raised central region. For example, if (e.g., when) Marangoni flow is stronger than capillary flow, the thickness of the emission layer 220 may become substantially non-uniform, which may deteriorate the characteristics of the light-emitting diode.

At this time, in the display apparatus 1 according to one or more embodiments, the emission layer 220 may be formed to have a substantially uniform thickness by applying electrical signals to the first sub-pixel electrode 211a and the second sub-pixel electrode 211b during the drying process. For example, the first sub-pixel electrode 211a may be connected to the external device through the first connection wire CW1′ and the second sub-pixel electrode 211b may be connected to the external device through the second connection wire CW2′, so that the first sub-pixel electrode 211a and the second sub-pixel electrode 211b may receive alternating current signals.

When the alternating current signals are applied to the first sub-pixel electrode 211a and the second sub-pixel electrode 211b during the drying process, the flow of the emission layer forming material may be caused by an ACEO phenomenon. In the ACEO phenomenon, the solvent moves on two electrodes forming an electric field in an opposite direction to a direction in which the electrodes face each other, and thus, the flow is caused. Accordingly, if (e.g., when) the electric field is formed by applying the alternating current signals to the first sub-pixel electrode 211a and the second sub-pixel electrode 211b, which respectively have the structures described above, the flow in which the solvent moves from the central portion to the edge within the emission layer 220 may be caused.

Consequently, in a case where Marangoni flow is stronger than capillary flow in which the solvent moves to the edge, if (e.g., when) electrical signals are applied to the first sub-pixel electrode 211a and the second sub-pixel electrode 211b each having the structure illustrated in FIG. 9, the direction of capillary flow may be enhanced by ACEO, thereby relatively alleviating Marangoni flow. Accordingly, in the display apparatus according to one or more embodiments, because the emission layer forming material balances capillary flow and Marangoni flow during the drying process, the emission layer 220 may be formed to have a substantially uniform thickness.

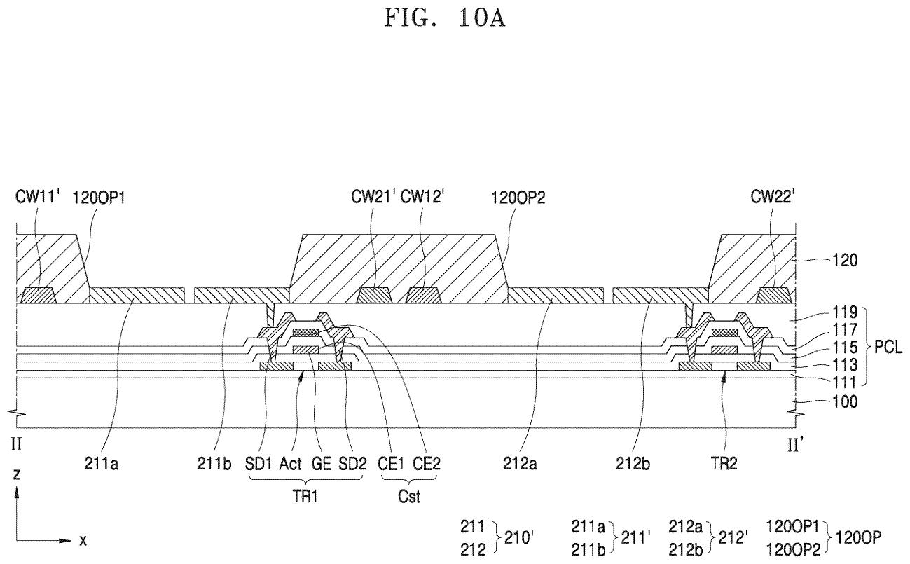

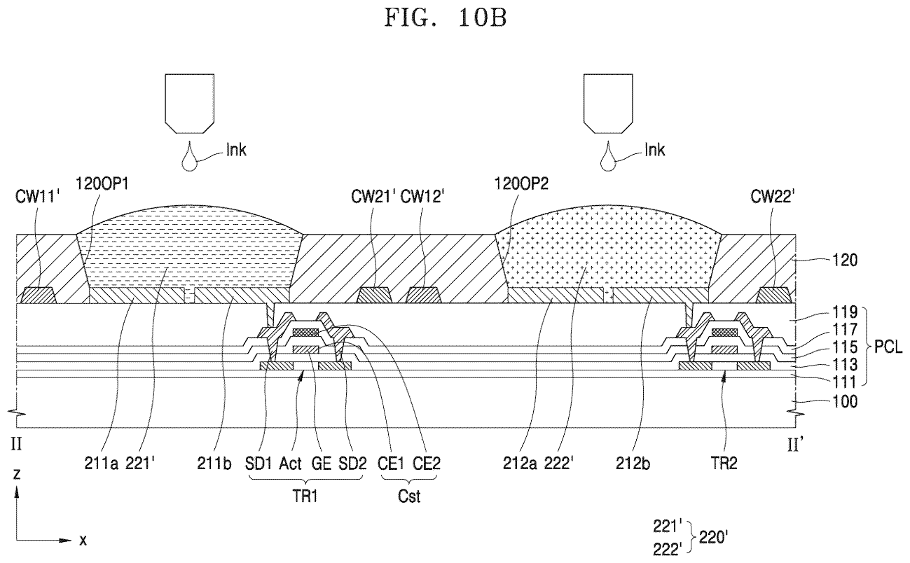

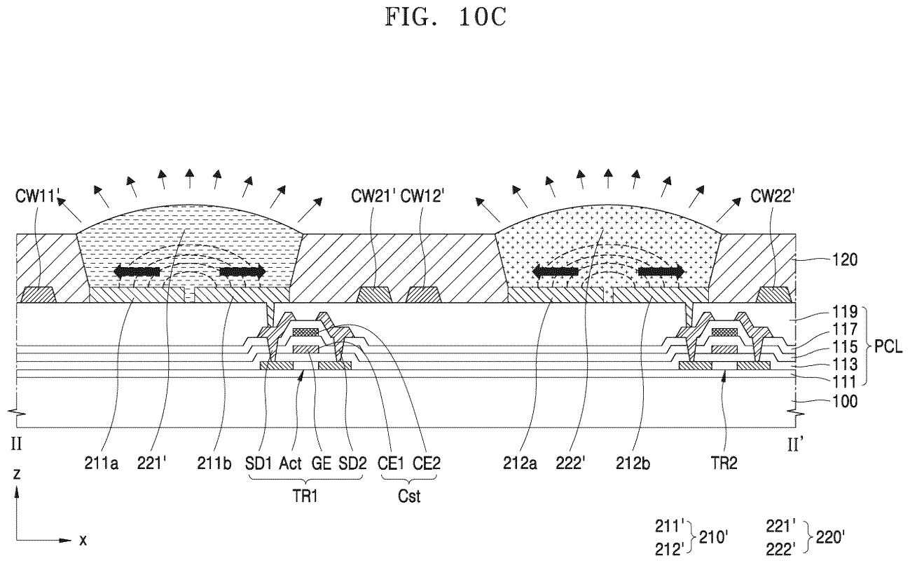

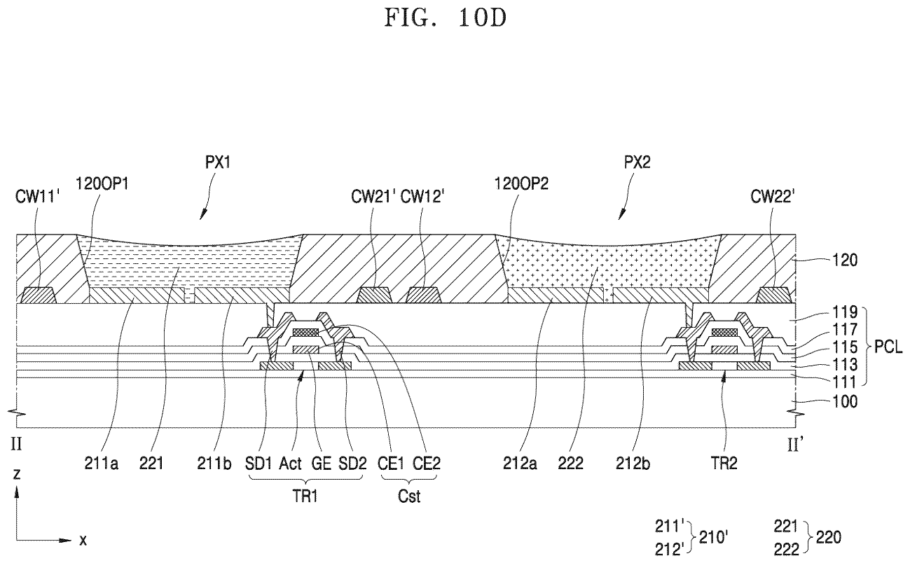

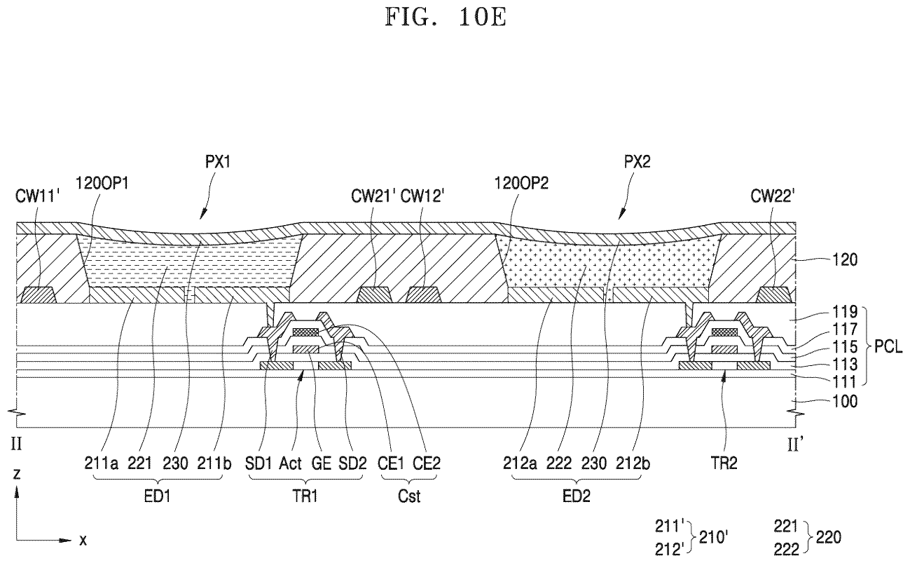

FIGS. 10A to 10E are cross-sectional views schematically illustrating a method of manufacturing a display apparatus, according to one or more embodiments. FIGS. 10A to 10E are cross-sectional views of the display apparatus of FIG. 8 taken along the line II-II′ of FIG. 8 according to the manufacturing process.

Referring to FIG. 10A, a pixel circuit layer PCL may be formed on a substrate 100, and a pixel electrode 210′ may be formed on the pixel circuit layer PCL.

For example, a first pixel electrode 211′ corresponding to a first pixel (see, e.g., PX1 of FIG. 9) and a second pixel electrode 212′ corresponding to a second pixel (see, e.g., PX2 of FIG. 9) may be formed on a planarization layer 119. In this case, the first pixel electrode 211′ may include a first sub-pixel electrode 211a and a second sub-pixel electrode 211b spaced and/or apart (e.g., spaced apart or separated) from each other by a certain distance, and the second pixel electrode 212′ may include a third sub-pixel electrode 212a and a fourth sub-pixel electrode 212b spaced and/or apart (e.g., spaced apart or separated) from each other by a certain distance.

In addition, a first connection wire CW1′ (see, e.g., FIG. 9) and a second connection wire CW2′ (see, e.g., FIG. 9) may be deposited on the planarization layer 119. The first connection wire CW1′ and the second connection wire CW2′ may be electrically connected to sub-pixel electrodes respectively arranged adjacent thereto.

The first sub-pixel electrode 211a, the second sub-pixel electrode 211b, the third sub-pixel electrode 212a, the fourth sub-pixel electrode 212b, the first connection wire CW1′, and the second connection wire. CW2′ may be formed to include the same material on the same layer. In this regard, the first sub-pixel electrode 211a, the second sub-pixel electrode 211b, the third sub-pixel electrode 212a, the fourth sub-pixel electrode 212b, the first connection wire CW1′, and the second connection wire. CW2′ may be concurrently (e.g., simultaneously) deposited through the same deposition process.

A bank layer 120 may be formed on the pixel electrode 210′, the first connection wire CW1′, and the second connection wire CW2′. The bank layer 120 may be formed to cover the end of the pixel electrode 210′ opposite to (e.g., facing) an edge of an opening 120OP, a top surface of the first connection wire CW1′, and a top surface of the second connection wire CW2′. The bank layer 120 may be formed by forming an inorganic insulating material layer or an organic insulating material layer and then patterning the opening 120OP to expose the central portion of the pixel electrode 210′.

Referring to FIG. 10B, by discharging ink including an emission layer forming material, a first material layer 221′ may be formed in a first opening 120OP1 and a second material layer 222′ may be formed in a second opening 120OP2. The first material layer 221′ and the second material layer 222′ may each constitute a material layer 220′. For example, the first material layer 221′ may be formed on the first sub-pixel electrode 211a and the second sub-pixel electrode 211b, and the second material layer 222′ may be formed on the third sub-pixel electrode 212a and the fourth sub-pixel electrode 212b. In one or more embodiments, the material layer 220′ may include a light-emitting material including quantum dots.

In one or more embodiments, the material layer 220′ may be formed through an inkjet printing process. The material layer 220′ may have a convex shape with a thick central portion, considering the surface tension and volume shrinkage after drying. However, the present disclosure is not limited thereto. In one or more embodiments, the material layer 220′ may have a flat shape or a concave shape according to an injection amount of ink including a light-emitting material.

Referring to FIG. 10C, an emission layer (see, e.g., 220 of FIG. 10D) may be formed by drying the material layer 220′. However, as described above, a solvent of the ink including the light-emitting material evaporates. When Marangoni flow phenomenon is strong, the emission layer (see, e.g., 220 of FIG. 10D) may have a W-shaped substantially non-uniform thickness.

Accordingly, in the method of manufacturing a display apparatus, according to one or more embodiments, electrical signals may be applied from an external device to the first sub-pixel electrode 211a and the second sub-pixel electrode 211b. An electrical signal may be transmitted to the first sub-pixel electrode 211a through a first-connection wire CW11′, and an electrical signal may be transmitted to the second sub-pixel electrode 211b through a first-2 connection wire CW21′.

The first sub-pixel electrode 211a and the second sub-pixel electrode 211b have a shape opposite to (e.g., have side ends facing) each other. Accordingly, if (e.g., when) alternating current signals are applied to the first sub-pixel electrode 211a and the second sub-pixel electrode 211b, an electric field may be formed between the first sub-pixel electrode 211a and the second sub-pixel electrode 211b, and thus, the solvent in the material layer 220′ may move from the central portion to the edge due to an ACEO phenomenon. For example, as illustrated in FIG. 10C, the solvent in the material layer 220′ may move from the central portion of the opening 120OP to the region adjacent to the bank layer 120.

When the flow occurs in the direction described above, the capillary flow may be enhanced, which weakens the effects caused by Marangoni flow, and thus, the material layer 220′ may be dried to have a substantially uniform thickness. Consequently, the light emission efficiency and lifespan efficiency of the light-emitting diode may be improved through the method of manufacturing a display apparatus, according to one or more embodiments. At this time, after the drying process is completed, the first connection wire CW1′ and the second connection wire CW2′ may be disconnected within a non-display area (see, e.g., NDA1 of FIG. 1).

Referring to FIG. 10D, after the drying of the emission layer 220 is completed, a bake process may be additionally performed. As the emission layer 220 is heat-treated in a condition of about 140° C. to about 230° C., the density inside the emission layer 220 may be increased and the light emission efficiency may be improved.

Specific conditions, such as the temperature and time of the bake process, may be appropriately or suitably selected according to the type or kind and capacity of the material. However, the present disclosure is not limited thereto. In some cases, the bake process may not be provided.

Referring to FIG. 10E, an opposite electrode 230 may be formed on the emission layer 220 and the bank layer 120. The opposite electrode 230 may be integrally formed across the entire surface of the substrate 100. Accordingly, the first sub-pixel electrode 211a, the second sub-pixel electrode 211b, the first emission layer 221, and the opposite electrode 230 may constitute a first light-emitting diode ED1, and the third sub-pixel electrode 212a, the fourth sub-pixel electrode 212b, the second emission layer 222, and the opposite electrode 230 may constitute a second light-emitting diode ED2.

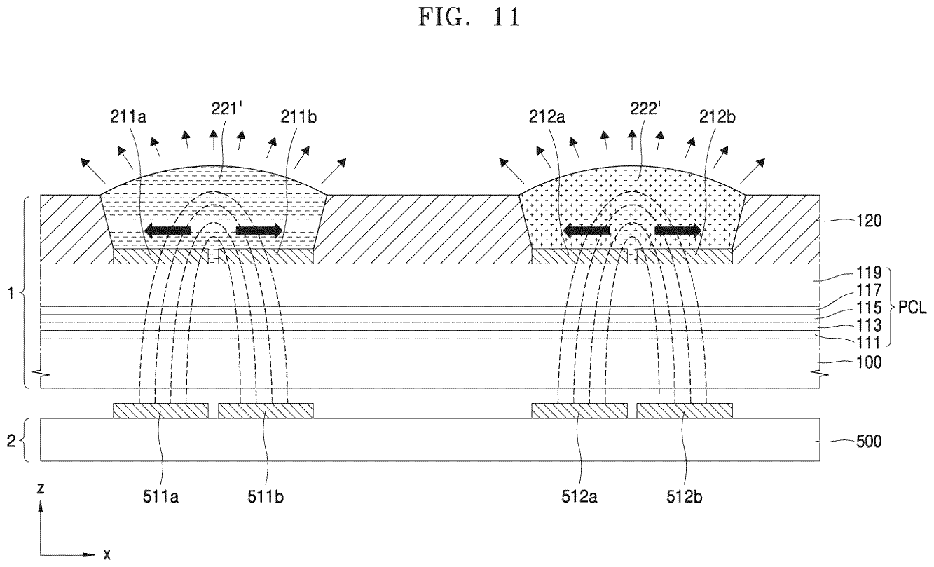

FIG. 11 is a cross-sectional view schematically illustrating a method of manufacturing a display apparatus, according to one or more embodiments. Referring to FIG. 11, other features except for a mobile device 2 may each independently be the same as described with reference to FIGS. 10A to 10E. In FIG. 11, the same reference numerals denote the same elements as those described with reference to FIGS. 10A to 10E and differences are mainly described in more detail later.

Referring to FIG. 11, an electric field may be formed by bringing the mobile device 2 close to the display apparatus 1. For example, the mobile device 2 may include an auxiliary substrate 500, first auxiliary electrode 511a, second auxiliary electrode 511b, third auxiliary electrode 512a, and fourth auxiliary electrode 512b.

Like the substrate 100, the auxiliary substrate 500 may include glass, metal, or polymer resin. Examples of the polymer resin may include polyethersulfone, polyacrylate, polyetherimide, polyethylene naphthalate, polyethylene terephthalate, polyphenylene sulfide, polyarylate, polyimide, polycarbonate, cellulose acetate propionate, or any mixture thereof. In one or more embodiments, other modifications are possible. For example, the auxiliary substrate 500 may have a multilayer structure that includes two layers and a barrier layer therebetween, wherein the two layers may include polymer resin and the barrier layer may include an inorganic material (e.g., silicon oxide (SiOₓ), silicon nitride (SiNₓ), silicon oxynitride (SiON), and/or the like).

However, in the mobile device 2, a pixel circuit layer PCL, and/or the like may not be, and first to fourth auxiliary electrodes 511a, 511b, 512a, and 512b may be deposited on the auxiliary substrate 500. Each of the first to fourth auxiliary electrodes 511a, 511b, 512a, and 512b may include conductive material capable of electric field induction. For example, each of the first to fourth auxiliary electrodes 511a, 511b, 512a, and 512b may include indium tin oxide (ITO), indium zinc oxide (IZO), tin oxide (SnO₂), zinc oxide (ZnO), or any combination thereof, or may include magnesium (Mg), silver (Ag), aluminum (Al), aluminum-lithium (Al—Li), calcium (Ca), magnesium-indium (Mg—In), magnesium-silver (Mg—Ag), or any combination thereof.

In this case, each of the first to fourth auxiliary electrodes 511a, 511b, 512a, and 512b may be formed in substantially the same shape as a shape of each of the first to fourth sub-pixel electrodes 211a, 211b, 212a, and 212b and may be formed to have the same area as an area of each of the first to fourth sub-pixel electrodes 211a, 211b, 212a, and 212b. In addition, the first to fourth auxiliary electrodes 511a, 511b, 512a, and 512b may be respectively formed at positions that may overlap the first to fourth sub-pixel electrodes 211a, 211b, 212a, and 212b in a plan view of the display apparatus 1 if (e.g., when) the substrate 100 and the auxiliary substrate 500 are aligned with each other. For example, the first auxiliary electrode 511a may be formed at the same position as a position of the first sub-pixel electrode 211a and may be formed to have the same area as an area of the first sub-pixel electrode 211, and the second auxiliary electrode 511b may be formed at the same position as a position of the second sub-pixel electrode 211b and may be formed to have the same area as an area of the second sub-pixel electrode 212.

At this time, in the method of manufacturing a display apparatus, according to one or more embodiments, in the process of drying the material layer 220′ so as to form the emission layer (see, e.g., 220 of FIG. 9), the mobile device 2 having the structure described above may be brought close to the display apparatus 1 and then connected to an external device that applies an electrical signal to the mobile device 2. For example, the external device may be connected to the first to fourth auxiliary electrodes 511a, 511b, 512a, and 512b of the mobile device 2 and may apply alternating current signals to the first to fourth auxiliary electrodes 511a, 511b, 512a, and 512b.

The external device may apply electrical signals of the same potential to the first auxiliary electrode 511a and the third auxiliary electrode 512a and may apply electrical signals of the same potential to the second auxiliary electrode 511b and the fourth auxiliary electrode 512b. Accordingly, if (e.g., when) the alternating current signals are applied to the first to fourth auxiliary electrodes 511a, 511b, 512a, and 512b, an electric field may be formed between the first auxiliary electrode 511a and the second auxiliary electrode 511b and an electric field may be formed between the third auxiliary electrode 512a and the fourth auxiliary electrode 512b.

As the mobile device 2 in which the electric field is formed is brought close to the display apparatus 1, the electric field formed between the first auxiliary electrode 511a and the second auxiliary electrode 511b may affect the material layer 220′. In particular, because the first auxiliary electrode 511a and the second auxiliary electrode 511b have a shape opposite to (e.g., have side ends facing) each other with respect to the center of the opening 120OP, the solvent in the material layer 220′ may move from the central portion to the edge due to an ACEO phenomenon.

As illustrated in FIG. 11, if (e.g., when) the mobile device 2 is brought close to the display apparatus 1 and the flow occurs in the direction described above, the effect due to capillary flow may be enhanced, and thus, the material layer 220′ may be dried to have a substantially uniform thickness. Consequently, the light emission efficiency and lifespan efficiency of the light-emitting diode may be improved through the method of manufacturing a display apparatus, according to one or more embodiments.

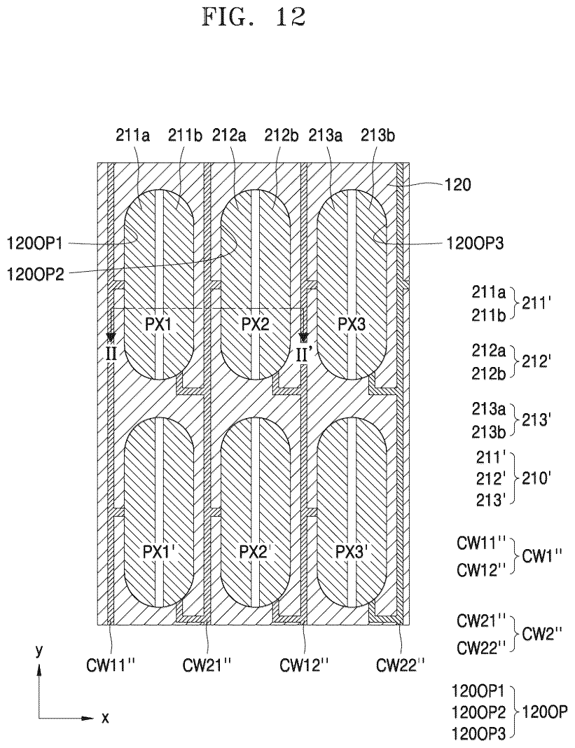

FIG. 12 is a schematic plan view of a display apparatus according to one or more embodiments. Referring to FIG. 12, other features except for a first connection wire CW1″ and a second connection wire CW2″ may each independently be the same as those described with reference to FIGS. 8 and 9. In FIG. 12, the same reference numerals denote the same elements as those described with reference to FIGS. 8 and 9 and differences are mainly described in more detail later.

Referring to FIG. 12, the display apparatus according to one or more embodiments may further include a connection wire that electrically connects each of sub-pixel electrodes to an external device that applies an electrical signal. The connection wire may include the first connection wire CW1″ and the second connection wire CW2″ respectively configured to transmit electrical signals to two sub-pixel electrodes corresponding to one pixel (see, e.g., PX of FIG. 1).

The first connection wire CW1″ and the second connection wire CW2″ may be configured to transmit electrical signals to sub-pixel electrodes respectively arranged on both sides (e.g., opposite sides) of the connection wire. For example, a first-1 connection wire CW11″ may be electrically connected to a first sub-pixel electrode 211a, and a second-1 connection wire CW21″ may be electrically connected to a second sub-pixel electrode 211b and a third sub-pixel electrode 212a. Similarly, a first-2 connection wire CW12″ may be electrically connected to a fourth sub-pixel electrode 212b and a fifth sub-pixel electrode 213a, and a second-2 connection wire CW22″ may be electrically connected to a sixth sub-pixel electrode 213b.

Each of the first connection wire CW1″ and the second connection wire CW2″ may extend in the first direction (e.g., the y direction) so as to connect the sub-pixel electrode to the external device. At this time, each of the first connection wire CW1″ and the second connection wire CW2″ may be connected to only one sub-pixel electrode and may also be electrically connected to a plurality of sub-pixel electrodes arranged with each other along (e.g., in a row in) the first direction (e.g., the y direction).

In this case, electrical signals of the same potential may be applied to the sub-pixel electrodes connected to the first connection wire CW1″, and electrical signals of the same potential may be applied to the sub-pixel electrodes connected to the second connection wire CW2″. For example, the first sub-pixel electrode 211a, the fourth sub-pixel electrode 212b, and the fifth sub-pixel electrode 213a may respectively receive electrical signals of the same potential, and the second sub-pixel electrode 211b, the third sub-pixel electrode 212a, and the sixth sub-pixel electrode 213b may respectively receive electrical signals of the same potential.

For example, only one selected from among the first connection wire CW1″ and the second connection wire CW2″ may be between the pixels (see, e.g., PX of FIG. 1) adjacent to each other. For example, one connection wire may be between the pixels (see, e.g., PX of FIG. 1) adjacent to each other. The display apparatus according to one or more embodiments, an area between the pixels (see, e.g., PX of FIG. 1) may be reduced. Accordingly, the resolution may be improved and the effect of forming the emission layer (see, e.g., 220 of FIG. 9) having a substantially uniform thickness may also be achieved.

The display apparatus according to one or more embodiments may improve the light emission efficiency and lifespan of the light-emitting device by forming the intermediate layer having a substantially uniform thickness. These effects are only examples, and the scope of the present disclosure is not limited by such effects.

The display device, the electronic apparatus, the electronic equipment, or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

A person of ordinary skill in the art, in view of the present disclosure in its entirety, would appreciate that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

It should be understood that embodiments described herein should be considered in a descriptive sense only and not for purposes of limitation. Descriptions of features or aspects within each embodiment should typically be considered as available for other similar features or aspects in one or more embodiments. While one or more embodiments have been described with reference to the drawings, it will be understood by those of ordinary skill in the art that one or more suitable changes in form and details may be made therein without departing from the spirit and scope as defined by the following claims and equivalents thereof.

What is claimed is:

1. A display apparatus comprising:
a substrate having a display area and a non-display area surrounding the display area;
a pixel circuit layer on the substrate, the pixel circuit layer comprising a pixel circuit and a planarization layer covering the pixel circuit;
a first main pixel electrode on the planarization layer;
a peripheral pixel electrode on the planarization layer, the peripheral pixel electrode being spaced from the first main pixel electrode and surrounding the first main pixel electrode in a plan view;
a bank layer comprising a first opening exposing a central portion of the first main pixel electrode;
a first intermediate layer corresponding to the first main pixel electrode and arranged within the first opening; and
an opposite electrode covering the bank layer and the first intermediate layer.

2. The display apparatus of claim 1, wherein the first main pixel electrode and the peripheral pixel electrode are arranged on a same layer.

3. The display apparatus of claim 1, wherein the bank layer covers a top surface and covers an end of the peripheral pixel electrode.

4. The display apparatus of claim 1, further comprising:
a second main pixel electrode on the planarization layer and arranged adjacent to the first main pixel electrode; and
a second intermediate layer arranged within a second opening of the bank layer which exposes a central portion of the second main pixel electrode,
wherein the peripheral pixel electrode is between the first main pixel electrode and the second main pixel electrode.

5. The display apparatus of claim 4, wherein each of the first intermediate layer and the second intermediate layer comprises an emission layer comprising quantum dots.

6. The display apparatus of claim 1, further comprising:
a first connection wire electrically connected to the first main pixel electrode and configured to transmit an electrical signal from an external device; and
a second connection wire electrically connected to the peripheral pixel electrode and configured to transmit an electrical signal from the external device.

7. The display apparatus of claim 6, wherein the first connection wire is electrically connected to a plurality of main pixel electrodes arranged with each other along a first direction.

8. The display apparatus of claim 6, wherein the first connection wire and the second connection wire are disconnected within the non-display area.

9. The display apparatus of claim 6, wherein the first connection wire is on a layer that is different from the first main pixel electrode.

10. A method of manufacturing a display apparatus, the method comprising:
forming a pixel circuit layer comprising a pixel circuit and a planarization layer covering the pixel circuit on a substrate;
forming a main pixel electrode on the planarization layer;
forming a peripheral pixel electrode on the planarization layer, the peripheral pixel electrode being spaced from the main pixel electrode and surrounding the main pixel electrode in a plan view;
forming a bank layer comprising an opening exposing a central portion of the main pixel electrode;
forming an intermediate layer corresponding to the main pixel electrode within the opening; and
forming an opposite electrode covering the bank layer and the intermediate layer.

11. The method of claim 10, wherein the main pixel electrode and the peripheral pixel electrode are deposited through a same process.

12. The method of claim 10, wherein the bank layer covers a top surface and an end of the peripheral pixel electrode.

13. The method of claim 10, wherein the forming of the intermediate layer comprises:
forming, on the main pixel electrode, a material layer for forming the intermediate layer; and
drying the material layer.

14. The method of claim 13, wherein the forming of the intermediate layer further comprises baking the dried material layer.

15. The method of claim 13, wherein the forming of the material layer comprises discharging, through an inkjet process, an intermediate layer forming material into the opening.

16. The method of claim 13, further comprising:
forming a first connection wire electrically connected to the main pixel electrode and being further extended to be connected to an external device; and
forming a second connection wire electrically connected to the peripheral pixel electrode and being further extended to be connected to the external device.

17. The method of claim 16, wherein the drying of the material layer comprises:
applying an alternating current signal from the external device to the main pixel electrode through the first connection wire; and
applying an alternating current signal from the external device to the peripheral pixel electrode through the second connection wire.

18. The method of claim 17, wherein the drying of the material layer further comprises generating an alternating-current electro-osmosis (ACEO) phenomenon within the material layer.

19. The method of claim 16, further comprising disconnecting the first connection wire and the second connection wire within a non-display area of the substrate.

20. The method of claim 13, further comprising bringing a mobile device close to a back surface of the substrate, the mobile device comprising an auxiliary substrate, a first auxiliary electrode on the auxiliary substrate, and a second auxiliary electrode on the auxiliary substrate,
wherein the first auxiliary electrode has a same area as an area of the main pixel electrode, and
the second auxiliary electrode has a same area as an area of the peripheral pixel electrode.

21. The method of claim 20, wherein the drying of the material layer comprises applying alternating current signals from an external device to the first auxiliary electrode and the second auxiliary electrode.

22. A display apparatus comprising:
a substrate having a display area and a non-display area surrounding the display area;
a pixel circuit layer on the substrate, the pixel circuit layer comprising a pixel circuit and a planarization layer covering the pixel circuit;
a first sub-pixel electrode on the planarization layer;
a second sub-pixel electrode on the planarization layer and spaced from the first sub-pixel electrode;
a bank layer having a first opening exposing a portion of the first sub-pixel electrode and a portion of the second sub-pixel electrode;
a first intermediate layer on the first sub-pixel electrode and the second sub-pixel electrode and arranged within the first opening; and
an opposite electrode covering the bank layer and covering the first intermediate layer.

23. The display apparatus of claim 22, wherein the first sub-pixel electrode and the second sub-pixel electrode are arranged on a same layer.

24. The display apparatus of claim 22, wherein the first sub-pixel electrode and the second sub-pixel electrode have a same area and respectively have shapes that are symmetrical with each other.

25. The display apparatus of claim 22, wherein each of the first sub-pixel electrode and the second sub-pixel electrode is electrically connected to the pixel circuit.

26. The display apparatus of claim 22, further comprising:
a first connection wire electrically connected to the first sub-pixel electrode and configured to transmit an electrical signal from an external device; and
a second connection wire electrically connected to the second sub-pixel electrode and configured to transmit an electrical signal from the external device.

27. The display apparatus of claim 26, further comprising:
a third sub-pixel electrode on the planarization layer and arranged adjacent to the second sub-pixel electrode;
a fourth sub-pixel electrode on the planarization layer and spaced from the third sub-pixel electrode; and
a second intermediate layer arranged within a second opening of the bank layer which exposes a portion of the third sub-pixel electrode and a portion of the fourth sub-pixel electrode.

28. The display apparatus of claim 27, wherein each of the first connection wire and the second connection wire are between the second sub-pixel electrode and the third sub-pixel electrode.

29. The display apparatus of claim 27, wherein only one selected from among the first connection wire and the second connection wire is between the second sub-pixel electrode and the third sub-pixel electrode.

30. The display apparatus of claim 26, wherein each of the first connection wire and the second connection wire is electrically connected to a plurality of sub-pixel electrodes arranged with each other along a first direction.

31. The display apparatus of claim 26, wherein the first connection wire and the second connection wire are disconnected within the non-display area.

32. A method of manufacturing a display apparatus, the method comprising:
forming a pixel circuit layer comprising a pixel circuit and a planarization layer covering the pixel circuit on a substrate;
forming a first sub-pixel electrode on the planarization layer;
forming a second sub-pixel electrode on the planarization layer, the second sub-pixel electrode being spaced from the first sub-pixel electrode;
forming a bank layer having an opening exposing a portion of the first sub-pixel electrode and a portion of the second sub-pixel electrode;
forming an intermediate layer on the first sub-pixel electrode and the second sub-pixel electrode within the opening; and
forming an opposite electrode covering the bank layer and the intermediate layer.

33. The method of claim 32, wherein the first sub-pixel electrode and the second sub-pixel electrode are deposited through a same process.

34. The method of claim 32, wherein the first sub-pixel electrode and the second sub-pixel electrode are in a same shape and have a same area.

35. The method of claim 32, wherein the forming of the intermediate layer comprises:
forming, on the first sub-pixel electrode and the second sub-pixel electrode, a material layer for the intermediate layer; and
drying the material layer.

36. The method of claim 35, wherein the forming of the material layer comprises discharging, through an inkjet process, an intermediate layer forming material into the opening.

37. The method of claim 35, further comprising:
forming a first connection wire electrically connected to the first sub-pixel electrode and being further extended to be connected to an external device; and
forming a second connection wire electrically connected to the second sub-pixel electrode and being further extended to be connected to the external device.

38. The method of claim 37, wherein the drying of the material layer comprises:
applying an alternating current signal from the external device to the first sub-pixel electrode through the first connection wire; and
applying an alternating current signal from the external device to the second sub-pixel electrode through the second connection wire.

39. The method of claim 38, wherein the drying of the material layer further comprises generating an alternating-current electro-osmosis (ACEO) phenomenon within the material layer.

40. The method of claim 37, further comprising disconnecting the first connection wire and the second connection wire within a non-display area of the substrate.

41. The method of claim 35, further comprising bringing a mobile device close to a back surface of the substrate, the mobile device comprising an auxiliary substrate, a first auxiliary electrode on the auxiliary substrate, and a second auxiliary electrode on the auxiliary substrate,
wherein an area of the first auxiliary electrode and an area of the first sub-pixel electrode are the same, and
an area of the second auxiliary electrode and an area of the second sub-pixel electrode are the same.

42. The method of claim 41, wherein the drying of the material layer comprises applying alternating current signals from an external device to the first auxiliary electrode and the second auxiliary electrode.
